(19) United States
(12) Patent Application Publication
(10) Pub. No.: US 2025/0298217 A1
(43) Pub. Date: Sep. 25, 2025

(54) MIRROR SOCKET, OPTICAL SYSTEM AND PROJECTION EXPOSURE APPARATUS

(71) Applicant: Carl Zeiss SMT GmbH, Oberkochen (DE)

(72) Inventors: Roman ORLIK, Koenigsbronn-Zang (DE); Daniel PAETZ, Erfurt (DE); Anastasia GARATIDOU, Ulm (DE); Johannes KRUIS, Oberkochen (DE); Marwene NEFZI, Aachen (DE); Klaus RIEF, Aalen-Oberalfingen (DE)

(21) Appl. No.: 19/229,313

(22) Filed: Jun. 5, 2025

Related U.S. Application Data
(63) Continuation of application No. PCT/EP2023/083642, filed on Nov. 30, 2023.

(30) Foreign Application Priority Data
Dec. 9, 2022 (GR) 20220101024
Jan. 10, 2023 (DE) 10 2023 100 393.3

(51) Int. Cl. G02B 7/182

(52) U.S. Cl. CPC G02B 7/182

(57) ABSTRACT

A mirror socket for an optical element, comprising: a centre axis; a first spatial direction oriented perpendicular to the centre axis; and a second spatial direction oriented perpendicular to the centre axis and perpendicular to the first spatial direction. The mirror socket has a first stiffness viewed in the first spatial direction and a second stiffness viewed in the second spatial direction. The first stiffness and the second stiffness have different magnitudes.

### CROSS-REFERENCE TO RELATED APPLICATIONS

The present application is a continuation of, and claims benefit under 35 USC 120 to, international application No. PCT/EP2023/08364, filed Nov. 30, 2023, which claims benefit under 35 USC 119 of Greek Application No. 20220101024, filed Dec. 9, 2022, and German Application No. 10 2023 100 393.3, filed Jan. 10, 2023. The entire disclosure of each of these applications is incorporated by reference herein.

### FIELD

The present disclosure relates to a mirror socket for an optical element, to an optical system having such a mirror socket and to a projection exposure apparatus having such a mirror socket and/or such an optical system.

### BACKGROUND

Microlithography is used for the production of microstructured components, for example integrated circuits. The microlithography process is carried out using a lithography apparatus, which has an illumination system and a projection system. The image of a mask (reticle) illuminated via the illumination system is projected here via the projection system onto a substrate, for example a silicon wafer, which is coated with a light-sensitive layer (photoresist) and arranged in the image plane of the projection system, in order to transfer the mask structure to the light-sensitive coating of the substrate. Driven by the desire for ever smaller structures in the production of integrated circuits, EUV lithography apparatuses that use light at a wavelength ranging from 0.1 nanometer (nm) to 30 nm, for example 13.5 nm, are currently under development. In the case of such EUV lithography apparatuses, because of the high absorption of light at this wavelength by most materials, reflective optical units, which is to say mirrors, are typically used instead of—as previously—refractive optical units, which is to say lens elements.

With the aid of mirror sockets, a mirror as mentioned above of a projection system may be coupled to a support structure, for example in the form of a force frame, or to actuators for aligning the mirror. To this end, the mirror sockets are often adhesively bonded to the mirror. The mirror has six degrees of freedom, specifically three translational degrees of freedom along a first spatial direction, a second spatial direction and a third spatial direction, and three rotational degrees of freedom, in each case about the aforementioned spatial directions.

Exactly three mirror sockets are often provided, with each mirror socket being assigned exactly two degrees of freedom. However, this is not mandatory. By way of example, it is also possible for one mirror socket to be assigned three degrees of freedom, a further mirror socket to be assigned two degrees of freedom and a further mirror socket to be assigned one degree of freedom. To introduce as few forces as possible into the mirror, as this may lead to unwanted deformations of the mirror for example, it is desirable for the mirror sockets to have stiffnesses of different magnitudes in different spatial directions.

### SUMMARY

The present disclosure seeks to provide an improved mirror socket for an optical element. A mirror socket for an optical element is proposed. The mirror socket comprises a centre axis, a first spatial direction oriented perpendicular to the centre axis and a second spatial direction oriented perpendicular to the centre axis and perpendicular to the first spatial direction, wherein the mirror socket has a first stiffness viewed in the first spatial direction and a second stiffness viewed in the second spatial direction and wherein the first stiffness and the second stiffness have different magnitudes.

As a result of the mirror socket having stiffnesses of different magnitudes viewed in the first spatial direction and in the second spatial direction, it is possible to arrange a plurality of mirror sockets carrying the optical element in such a way that no unwanted forces or moments are introduced into the optical element. Unwanted deformations of an optically effective surface of the optical element can be avoided as a result. This can improve the imaging quality of a projection exposure apparatus having such a mirror socket.

The optical element can be a mirror module or a mirror, such as an EUV mirror, or can be referred to as mirror module or mirror. However, the optical element can also be a lens element. Optionally, a plurality of mirror sockets, for example exactly three, are assigned to the optical element. Only one mirror socket is discussed in more detail hereinafter. The optical element has an optically effective surface, for example a mirror surface. The optical element, and especially the optically effective surface, is suitable for reflecting illumination radiation, for example EUV radiation. The optically effective surface can be a coating that is applied to a substrate, for example a glass block or a glass ceramic block. Optionally, the mirror socket can be integrally bonded to the optical element, for example to a back side of the optical element. Integrally bonded connections are connections in which the connection partners are held together by atomic or molecular forces. At the same time, they are non-releasable connections that can be separated only by destruction of the connection mechanism and/or the connection partners. By way of example, the mirror socket is adhesively bonded to the optical element.

The mirror socket can be constructed in rotationally symmetric fashion with respect to the centre axis. Optionally, the mirror socket is constructed in substantially rotationally symmetric fashion with respect to the centre axis. In this case “substantially” means that it is not possible to rule out that the mirror socket also has regions or portions which are not constructed in rotationally symmetric fashion with respect to the centre axis. The centre axis may also be referred to as the axis of symmetry of the mirror socket. For example, at least an outer part and/or an inner part of the mirror socket are constructed in rotationally symmetric fashion with respect to the centre axis. However, the rotational symmetry is not mandatory.

Each mirror socket can be assigned a coordinate system having the first spatial direction, which may also be referred to as x-direction, the second spatial direction, which may also be referred to as y-direction, and a third spatial direction or z-direction. The third spatial direction may be oriented parallel to the centre axis or may correspond to the latter. The second spatial direction is oriented perpendicular to the first spatial direction. The third spatial direction is oriented perpendicular to the first spatial direction and perpendicular to the second spatial direction. In the present case, “perpendicular” should be understood to mean an angle of 90°±10°, such as of 90°±5°, for example of 90°±3°, for example of 90°±1°, and for example of exactly 90°. The first spatial direction and the second spatial direction span a plane oriented perpendicular to the centre axis.

In the present case, the “stiffness” should be understood to mean very generally the resistance of a body, in the present case the mirror socket, to an elastic deformation impressed thereon by an external load and conveys the relationship between the load on the body and its deformation. The stiffness is determined by the material in the body and its geometry. For example, the first stiffness and the second stiffness having different magnitudes can be achieved by adapting a geometry of the mirror socket. Optionally, the second stiffness is greater than the first stiffness.

For example, the mirror socket has a third stiffness viewed along the centre axis or in the third spatial direction. The third stiffness can be greater than the first stiffness and greater than the second stiffness. The first stiffness and the second stiffness having “different” magnitudes in the present case means that, in particular, the second stiffness is greater than the first stiffness. Alternatively, the first stiffness can also be greater than the second stiffness.

According to an embodiment, the mirror socket further comprises an outer part, an inner part arranged within the outer part and elastically deformable connecting parts, with the outer part being connected to the inner part with the aid of the connecting parts.

The outer part can be ring shaped. Therefore, the outer part may also be referred to as outer ring. The outer part can be constructed in rotationally symmetric fashion with respect to the centre axis. The inner part can be ring shaped. Therefore, the inner part may also be referred to as inner ring. The inner part can be constructed in rotationally symmetric fashion with respect to the centre axis. Optionally, the outer part is connected to the optical element, for example adhesively bonded thereto. The inner part can be connected to a support structure, for example in the form of a force frame. The inner part serves as an interface to surroundings. In the present case, the “surroundings” can be understood to mean the aforementioned support structure or an actuator or actuators. By way of example, the inner part is clamped with and/or screwed to the support structure. The support structure has a joining point, for example comprising a screwed connection, for joining the inner part. Conversely, it is also possible for the outer part to be connected to the support structure and the inner part to be connected to the optical element.

The connecting parts act as what are known as flexures and allow a movement of the inner part relative to the outer part, or vice versa. In the present case, a “flexure” is generally understood to mean a region, for example a cross-sectional narrowing or thinning, of a component, which region enables a relative movement between two rigid-body regions of the component by bending or torsion. In the present case, the outer part and the inner part can form the rigid body regions, between which the elastically deformable connecting parts are provided as flexures. The connecting parts themselves may additionally have grooves, cross-sectional narrowings or cross-sectional thinnings, which act as flexures provided directly on the connecting parts. This achieves a further improved deformability of the connecting parts.

In the present case, the fact that the connecting parts are “elastically” or “resiliently” deformable means that, in particular, the connecting parts can be brought from a non-deformed state into a deformed state with the aid of a force or a moment. As soon as the force or the moment no longer acts on the respective connecting part, the latter is brought back automatically from the deformed state to the non-deformed state. For example, the connecting parts thus are resiliently deformable.

Each connecting part can have a cross-sectional area that can be shaped as desired. For example, the cross-sectional area is rectangular, triangular, round, cruciform or the like. The connecting parts have a connecting part width and a connecting part height. In the present case, an “aspect ratio” may be understood to mean a ratio of connecting part height to connecting part width. The stiffness of the connecting parts can be modified by changing the aspect ratio. It is desirable for a first connecting part and a second connecting part to be provided. That is to say, precisely two connecting parts may be provided. However, in general there are any desired number of connecting parts.

The cross-sectional area of the connecting parts may be constant viewed along a connecting part length of the connecting parts. In the present case, the “connecting part length” should be understood to mean a length of the respective connecting part along its main direction of extent, along which the connecting part, starting from the inner part, extends towards the outer part. The cross-sectional area may also change viewed along the connecting part length. For example, the cross-sectional area increases from the outer part, as a starting point, to the inner part, or vice versa.

In addition to the connecting parts, the inner part may also be suspended on the outer part with the aid of additional leaf springs. The leaf springs additionally stiffen the mirror socket along the centre axis or third spatial direction and stiffen the mirror socket only minimally in the two other spatial directions. The leaf springs can be folded. For example, each leaf spring has a first leaf spring portion and a second leaf spring portion. The leaf spring portions can be inclined with respect to one another. By way of example, the first leaf spring portion and the second leaf spring portion may be oriented perpendicular to one another.

The connecting parts can extend in the spatial direction of the two spatial directions which provides for the greater stiffness along it. This can be the second spatial direction or y-direction. However, the connecting parts may also extend in the first spatial direction or x-direction. In this latter case, the mirror socket has its greater stiffness viewed in the first spatial direction or x-direction. The mirror socket can have its greatest stiffness viewed in the third spatial direction or z-direction. That is to say, the stiffness of the mirror socket viewed in the third spatial direction or z-direction is greater than in the other two spatial directions.

According to an embodiment, the connecting parts extend in the spatial direction viewed along which the mirror socket has the greater stiffness.

As mentioned previously, this can be the second spatial direction or y-direction. In this case, the connecting parts may extend linearly along this spatial direction. However, the connecting parts may also be curved, for example arcuately curved. Optionally, the connecting parts extend in the second spatial direction or y-direction. Accordingly, the mirror socket can have a lower stiffness viewed perpendicular to the connecting parts than along the connecting parts.

According to an embodiment, the inner part is arranged between a first connecting part and a second connecting part.

There can in general be any desired number of connecting parts. However, it is desirable for exactly two connecting parts to be provided, between which the inner part is placed. The connecting parts can be connected to the inner part with the aid of joining points that act as flexures. By way of example, the connecting parts can be cut free from the outer part with the aid of slots. For example, the slots can be produced with the aid of a wire erosion method.

According to an embodiment, the outer part, the inner part and the connecting parts are connected to one another in integral, for example materially integral, fashion.

Here, “one piece” or “integral” means that, in particular, the outer part, the inner part and the connecting parts form a common component, specifically the mirror socket, and are not put together from different subcomponents. In the present case, “materially integral” means that the outer part, the inner part and the connecting parts are fabricated from the same material throughout. The materially integral embodiment is optional. An implementation with different materials is also possible in general. Optionally, the mirror socket is fabricated from a metallic material. For example, an iron-nickel alloy, for example Invar, can be used. For example, the mirror socket can be produced with the aid of a milling method and/or a wire erosion method. However, the mirror socket can also be produced with the aid of an additive or generative production method, for example with the aid of a 3D printing method.

According to an embodiment, the connecting parts extend parallel to and spaced apart from one another.

As mentioned previously, the connecting parts can extend in the second spatial direction or y-direction. Viewed in the first spatial direction or x-direction, the connecting parts can be placed spaced apart from one another in such a way that the inner part can be placed between the connecting parts. For example, the connecting parts are connected on both end sides to the outer part and are connected centrally to the inner part. According to an embodiment, the connecting parts have arcuate, for example circularly arcuate, curvature.

Thus, the connecting parts can extend around the inner part at least in portions. Thus, the connecting parts can run around or surround the inner part. As a result of the arcuate geometry of the connecting parts, it is possible to increase the connecting part length of the connecting parts in comparison with a straight arrangement of the connecting parts.

According to an embodiment, the connecting parts each have a first connecting part portion and a second connecting part portion, wherein the first connecting part portion and the second connecting part portion are connected to one another with the aid of deflection portions such that the connecting parts have a circumferentially closed geometry.

In this case, the connecting part portions may extend in a straight line and parallel to one another. Alternatively, the connecting part portions may also have arcuate, for example circularly arcuate, curvature. The connecting part portions may extend parallel to one another in this case, too. Together, the connecting part portions and the deflection portions form a circumferentially closed geometry, for example a ring-shaped geometry. For example, the connecting parts are O shaped. Accordingly, the term “ring shaped” also comprises closed geometries that are not circular. Alternatively, the connecting part portions and the deflection portions may also be arranged in such a way that the connecting parts have a circumferentially open geometry. In this case, the connecting parts can be zigzag shaped or have meandering curvature, for example.

According to an embodiment, the connecting parts jointly form a ring connecting part, which runs around the inner part at least in portions.

The inner part is placed within the ring connecting part. The ring connecting part may be circumferentially closed. In this case, the ring connecting part runs completely around the inner part. The ring connecting part may be connected to the inner part with the aid of joining points and to the outer part with the aid of further joining points. The joining points of the inner part and the joining points of the outer part can be placed with an offset of 90° from one another. Alternatively, the ring connecting part may also be circumferentially open. For example, the ring connecting part is connected to the inner part with the aid of exactly one joining point and to the outer part with the aid of two joining points in this case. The ring connecting part can have a circular or else oval shape with principal axes of different length. Accordingly, “ring shaped” does not necessarily mean circular in the present case. Thus, not only the connecting part length but also a curve shape of the connecting parts can be used to adapt the stiffness in the x-direction and in the y-direction. A greater stiffness can be obtained in the direction of the longer principal axis. A lesser stiffness can be obtained across the major principal axis, which is to say along the minor principal axis.

According to an embodiment, the connecting parts have a connecting part height viewed along the centre axis, wherein, starting from the outer part, the connecting part height varies in the direction of the inner part.

In this case, “varies” means that, in particular, the connecting part height changes, for example becomes higher or lower. By way of example, this can be achieved by milling, bevelling or the like. The stiffness of the connecting parts can be adapted as a result. As a result, an installation space-restricting volume can be used efficiently.

According to an embodiment, the mirror socket contains drilled holes, through which a cutting wire can be guided for the purpose of producing the mirror socket.

This can help facilitate the mirror socket producibility.

According to an embodiment, the mirror socket is fabricated from an amagnetic material, for example from molybdenum.

This can enable the use of the mirror socket in magnetic fields as well. Magnetostriction effects are decisive here, as these may lead to a deformation of the material of the mirror socket in the case of a magnetic field change. For example, use can be made of a molybdenum-containing alloy. The term “amagnetic” can be replaced by the term “nonmagnetic”. Alternatively, the mirror socket can also be fabricated from an iron-nickel alloy for example, for example from Invar.

An optical system for a projection exposure apparatus is also proposed. The optical system comprises an optical element, a support structure for carrying the optical element and at least one such mirror socket, wherein the optical element is connected to the support structure with the aid of the at least one mirror socket.

The optical system may comprise any desired number of optical elements and/or mirror sockets. The optical system can be a projection optical unit or a part of such a projection optical unit. Therefore, the optical system can also be referred to as projection optical unit. However, the optical system can also be an illumination system or a part of such an illumination system. Therefore, the optical system can alternatively also be referred to as illumination system. However, the assumption is made below that the optical system is a projection optical unit or part of such a projection optical unit. The optical system is suitable for EUV lithography. However, the optical system can also be suitable for DUV lithography.

As mentioned above, the optical element can be a mirror, for example an EUV mirror. The support structure can be a force frame as mentioned above. In the present case, the support structure “carrying” the optical element means that, in particular, the support structure is able to absorb a weight of the optical element. Thus, for example, a weight of the optical element can be transferred to the support structure via the mirror socket. The mirror socket can have the object of mechanically decoupling the optical element from the support structure such that no parasitic forces, which for example may lead to an unwanted deformation of the optical element, are introduced into the optical element at the mirror socket.

Optionally, a plurality of mirror sockets are assigned to the optical element. The mirror sockets couple the optical element to the support structure. The optical element has six degrees of freedom, specifically three translational degrees of freedom in each case along the first spatial direction or x-direction, the second spatial direction or y-direction, and the third spatial direction or z-direction, and also three rotational degrees of freedom in each case about the three spatial directions. That is to say, a position and an orientation of the optical element can be determined or described with the aid of the six degrees of freedom.

The “position” of the optical element should be understood to mean in particular its coordinates in relation to the x-direction, the y-direction and the z-direction. The “orientation” of the optical element should be understood to mean in particular its tilt in relation to the three spatial directions. That is to say, the optical element can be tilted about the x-direction, the y-direction and/or the z-direction. This gives six degrees of freedom for the position and orientation of the optical element.

A “pose” of the optical system comprises both its position and its orientation. The term “pose” is accordingly replaceable by the wording “position and orientation”, and vice versa. In the present case, an “adjustment” or “alignment” of the optical element is understood to mean in particular a change in the pose of the optical element. Adjusting or aligning the optical element can be implemented in several or all of the six aforementioned degrees of freedom. For example, underlay elements, for example in the form of washers, may be placed under the mirror sockets in order to adjust the pose of the optical element.

According to an embodiment, the optical system also comprises three mirror sockets, wherein the optical element has six degrees of freedom and wherein each mirror socket is assigned exactly two of the degrees of freedom.

For example, each mirror socket has high stiffness in the two degrees of freedom assigned to the respective mirror socket and less stiffness in the four remaining degrees of freedom. However, this is not mandatory. By way of example, it is also possible for one mirror socket to be assigned three degrees of freedom, a further mirror socket to be assigned two degrees of freedom and a further mirror socket to be assigned one degree of freedom. The three mirror sockets can be placed at corners of an imaginary triangle formed by the three mirror sockets.

According to an embodiment, each of the three mirror sockets has a plane spanned by the centre axis and the spatial direction viewed along which the mirror socket has the smaller stiffness, wherein the three mirror sockets are arranged such that the planes intersect one another in a common line of intersection.

For example, the plane is spanned by the centre axis or third spatial direction or z-direction and the first spatial direction or x-direction. Hence, the mirror socket has its greatest stiffness perpendicular to this plane, which is to say viewed in the second spatial direction or y-direction. Optionally, the three mirror sockets are arranged such that their lateral flexible direction in each case points radially in the direction of a centre of the optical element and their laterally stiff direction is oriented perpendicular thereto. For example, the line of intersection lies at the centre of the optical element.

Furthermore, a projection exposure apparatus having such a mirror socket and/or such an optical system is proposed.

The optical system can be a projection optical unit of the projection exposure apparatus. However, the optical system may also be an illumination system. The projection exposure apparatus may be an EUV lithography apparatus. EUV stands for “extreme ultraviolet” and refers to a wavelength of the working light of between 0.1 nm and 30 nm. The projection exposure apparatus may also be a DUV lithography apparatus. DUV stands for “deep ultraviolet” and refers to a wavelength of the working light of between 30 nm and 250 nm.

“A” or “an” or “one” in the present case should not necessarily be understood to be restrictive to exactly one element. Rather, a plurality of elements, such as two, three or more, may also be provided. Nor should any other numeral used here be understood to the effect that there is a restriction to exactly the stated number of elements. Instead, unless indicated otherwise, numerical deviations upward and downward are possible.

The embodiments and features described for the mirror socket are correspondingly applicable to the proposed optical system and/or to the proposed projection exposure apparatus, and vice versa.

Further possible implementations of the disclosure also comprise combinations which were not mentioned explicitly of features or embodiments described above or hereinafter with respect to the exemplary embodiments. In this case, a person skilled in the art will also add individual aspects as improvements or supplementations to the respective basic form of the disclosure.

Further refinements and aspects of the disclosure are the subject matter of the dependent claims and also of the exemplary embodiments of the disclosure that are described below. In addition, the disclosure will be explained in detail hereinafter on the basis of embodiments with reference to the appended figures.

### BRIEF DESCRIPTION OF THE DRAWINGS

FIG. 1 shows a schematic meridional section of a projection exposure apparatus for EUV projection lithography;

FIG. 2 shows a schematic view of an embodiment of an optical system for the projection exposure apparatus according to FIG. 1;

FIG. 3 shows a schematic plan view of the optical system according to FIG. 2;

FIG. 4 shows a schematic plan view of an embodiment of a mirror socket for the optical system in accordance with FIG. 2; FIG. 5 shows the sectional view V-V according to FIG. 4;

FIG. 6 shows a schematic perspective view of an embodiment of a mirror socket for the optical system according to FIG. 2;

FIG. 7 shows a schematic back view of the mirror socket according to FIG. 6;

FIG. 8 shows a schematic perspective view of an embodiment of a mirror socket for the optical system according to FIG. 2;

FIG. 9 shows a schematic back view of the mirror socket according to FIG. 6;

FIG. 10 shows a schematic perspective view of an embodiment of a mirror socket for the optical system according to FIG. 2;

FIG. 11 shows a schematic back view of the mirror socket according to FIG. 10;

FIG. 12 shows a schematic perspective view of an embodiment of a mirror socket for the optical system according to FIG. 2;

FIG. 13 shows a schematic back view of the mirror socket according to FIG. 12;

FIG. 14 shows a schematic perspective view of an embodiment of a mirror socket for the optical system according to FIG. 2;

FIG. 15 shows a schematic back view of the mirror socket according to FIG. 14;

FIG. 16 shows a schematic perspective view of an embodiment of a mirror socket for the optical system according to FIG. 2;

FIG. 17 shows a schematic back view of the mirror socket according to FIG. 16;

FIG. 18 shows a schematic perspective view of an embodiment of a mirror socket for the optical system according to FIG. 2;

FIG. 19 shows a schematic back view of the mirror socket according to FIG. 18;

FIG. 20 shows a schematic perspective view of an embodiment of a mirror socket for the optical system according to FIG. 2;

FIG. 21 shows a schematic back view of the mirror socket according to FIG. 20;

FIG. 22 shows a schematic perspective view of an embodiment of a mirror socket for the optical system according to FIG. 2;

FIG. 23 shows a schematic back view of the mirror socket according to FIG. 22;

FIG. 24 shows a schematic perspective view of an embodiment of a mirror socket for the optical system according to FIG. 2;

FIG. 25 shows a schematic back view of the mirror socket according to FIG. 24;

FIG. 26 shows a schematic perspective view of an embodiment of a mirror socket for the optical system according to FIG. 2;

FIG. 27 shows a schematic back view of the mirror socket according to FIG. 26;

FIG. 28 shows a schematic perspective view of an embodiment of a mirror socket for the optical system according to FIG. 2;

FIG. 29 shows a schematic back view of the mirror socket according to FIG. 28;

FIG. 30 shows a schematic perspective view of an embodiment of a mirror socket for the optical system according to FIG. 2;

FIG. 31 shows a schematic back view of the mirror socket according to FIG. 30;

FIG. 32 shows a schematic perspective view of an embodiment of a mirror socket for the optical system according to FIG. 2; and

FIG. 33 shows a schematic back view of the mirror socket according to FIG. 32;

### DETAILED DESCRIPTION

Unless indicated otherwise, elements that are identical or functionally identical have been provided with the same reference signs in the figures. It should also be noted that the illustrations in the figures are not necessarily true to scale.

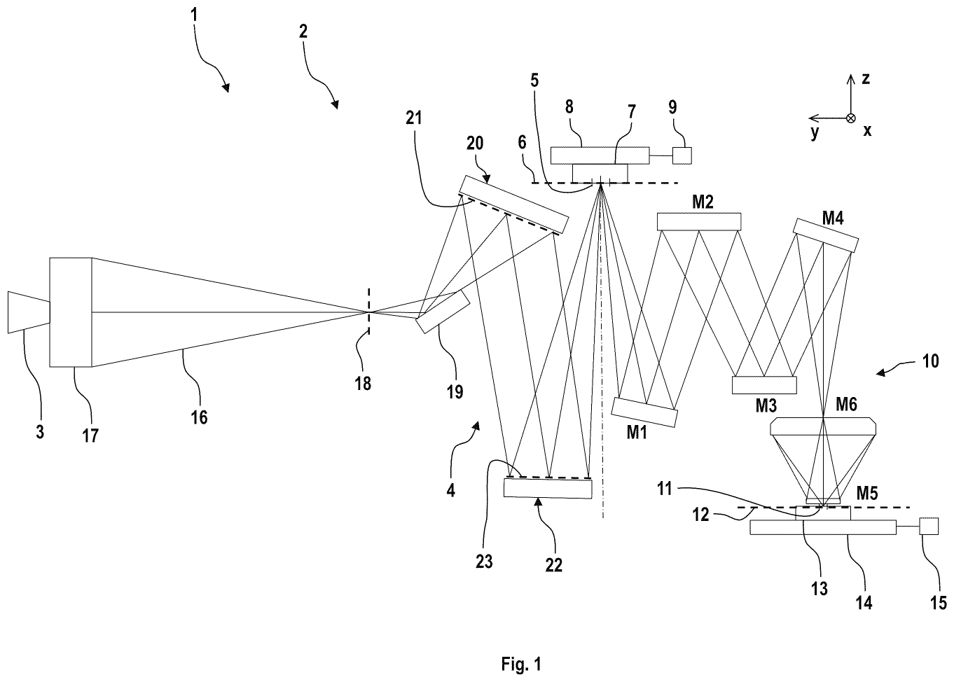

FIG. 1 shows an embodiment of a projection exposure apparatus 1 (lithography apparatus), for example an EUV lithography apparatus. One embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 shows, for explanatory purposes, a Cartesian coordinate system with an x-direction x, a y-direction y and a z-direction z. The x-direction x runs perpendicularly into the plane of the drawing. The y-direction y runs horizontally, and the z-direction z runs vertically. The scanning direction in FIG. 1 runs in the y-direction y. The z-direction z runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6.

Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement firstly of the reticle 7 by way of the reticle displacement drive 9, and secondly of the wafer 13 by way of the wafer displacement drive 15, can be implemented so as to be mutually synchronized.

The light source 3 is an EUV radiation source. The light source 3 emits EUV radiation 16, which is also referred to below as used radiation, illumination radiation or illumination light. For example, the used radiation 16 has a wavelength in the range between 5 nm and 30 nm. The radiation source 3 can be a plasma source, for example an LPP (laser produced plasma) source or a GDPP (gas discharge produced plasma) source. It may also be a synchrotron-based radiation source. The light source 3 can be a free electron laser (FEL).

The illumination radiation 16 emanating from the light source 3 is focused by a collector 17. The collector 17 can be a collector with one or more ellipsoidal and/or hyperboloidal reflection surfaces. The illumination radiation 16 can be incident on the at least one reflection surface of the collector 17 with grazing incidence (GI), which is to say at angles of incidence of greater than 45°, or with normal incidence (NI), which is to say at angles of incidence of less than 45°. The collector 17 may be structured and/or coated, firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 may represent a separation between a radiation source module, having the light source 3 and the collector 17, and the illumination optical unit 4.

The illumination optical unit 4 comprises a deflection mirror 19 and, arranged downstream thereof in the beam path, a first facet mirror 20. The deflection mirror 19 can be a plane deflection mirror or, alternatively, a mirror with a beam-influencing effect that goes beyond the purely deflecting effect. In an alternative or in addition, the deflection mirror 19 may be in the form of a spectral filter that separates a used light wavelength of the illumination radiation 16 from extraneous light at a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which may also be referred to as field facets. Only some of these first facets 21 are shown in FIG. 1 by way of example.

The first facets 21 may be embodied as macroscopic facets, for example as rectangular facets or as facets with an arcuate or part-circular edge contour. The first facets 21 may be in the form of plane facets or alternatively of facets with convex or concave curvature.

As is known for example from DE 10 2008 009 600 A1, the first facets 21 themselves may also each be composed of a multiplicity of individual mirrors, for example a multiplicity of micromirrors. The first facet mirror 20 may for example be in the form of a microelectromechanical system (MEMS system). For details, reference is made to DE 10 2008 009 600 A1.

Between the collector 17 and the deflection mirror 19, the illumination radiation 16 travels horizontally, which is to say in the y-direction y.

In the beam path of the illumination optical unit 4, a second facet mirror 22 is arranged downstream of the first facet mirror 20. Provided the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or may alternatively be facets composed of micromirrors. In this regard, reference is likewise made to DE 10 2008 009 600 A1.

The second facets 23 can have plane or, alternatively, convexly or concavely curved reflection surfaces.

The illumination optical unit 4 thus forms a double-faceted system. This principle is also referred to as a fly's eye integrator.

It may be advantageous to arrange the second facet mirror 22 not exactly in a plane that is optically conjugate to a pupil plane of the projection optical unit 10. For example, the second facet mirror 22 may be arranged so as to be tilted in relation to a pupil plane of the projection optical unit 10, as is described for example in DE 10 2017 220 586 A1. With the aid of the second facet mirror 22, the individual first facets 21 are imaged into the object field 5. The second facet mirror 22 is the last beam-shaping mirror or else indeed the last mirror for the illumination radiation 16 in the beam path upstream of the object field 5.

In an embodiment (not illustrated) of the illumination optical unit 4, a transfer optical unit may be arranged in the beam path between the second facet mirror 22 and the object field 5, and contributes for example to the imaging of the first facets 21 into the object field 5. The transfer optical unit may comprise exactly one mirror or, alternatively, two or more mirrors, which are arranged in succession in the beam path of the illumination optical unit 4. The transfer optical unit may for example comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the first facet mirror 20, and the second facet mirror 22.

In an embodiment of the illumination optical unit 4, there is also no need for the deflection mirror 19, and so the illumination optical unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is often only approximate imaging.

The projection optical unit 10 comprises a plurality of mirrors Mi, which are consecutively numbered in accordance with their arrangement in the beam path of the projection exposure apparatus 1.

In the example shown in FIG. 1, the projection optical unit 10 comprises six mirrors M1 to M6. Alternatives with four, eight, ten, twelve or any other number of mirrors Mi are likewise possible. The projection optical unit 10 is a doubly obscured optical unit. The penultimate mirror M5 and the last mirror M6 each have a through opening for the illumination radiation 16. The projection optical unit 10 has an image-side numerical aperture that is greater than 0.5 and may also be greater than 0.6 and may be for example 0.7 or 0.75.

Reflection surfaces of the mirrors Mi may be designed as freeform surfaces without an axis of rotational symmetry. Alternatively, the reflection surfaces of the mirrors Mi may be designed as aspherical surfaces with exactly one axis of rotational symmetry of the reflection surface shape. Just like the mirrors of the illumination optical unit 4, the mirrors Mi may have highly reflective coatings for the illumination radiation 16. These coatings may be designed as multilayer coatings, for example with alternating layers of molybdenum and silicon.

The projection optical unit 10 has a large object-image offset in the y-direction y between a y-coordinate of a centre of the object field 5 and a y-coordinate of the centre of the image field 11. This object-image offset in the y-direction y may be of approximately the same magnitude as a z-distance between the object plane 6 and the image plane 12.

The projection optical unit 10 may for example have an anamorphic form. It has for example different imaging scales βx, βy in the x- and y-directions x, y. The two imaging scales βx, βy of the projection optical unit 10 can be (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction x, which is to say in a direction perpendicular to the scanning direction.

The projection optical unit 10 leads to a reduction in size of 8:1 in the y-direction y, which is to say in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 may be the same or may differ, depending on the embodiment of the projection optical unit 10. Examples of projection optical units with different numbers of such intermediate images in the x- and y-directions x, y are known from US 2018/0074303 A1.

In each case one of the second facets 23 is assigned to exactly one of the first facets 21 for respectively forming an illumination channel for illuminating the object field 5. This may for example result in illumination according to the Köhler principle. The far field is decomposed into a multiplicity of object fields 5 with the aid of the first facets 21. The first facets 21 produce a plurality of images of the intermediate focus on the second facets 23 respectively assigned to them.

By way of an assigned second facet 23, the first facets 21 are in each case imaged onto the reticle 7 in a manner overlaid on one another for the purposes of illuminating the object field 5. The illumination of the object field 5 is for example as homogeneous as possible. It can have a uniformity error of less than 2%. Field uniformity can be achieved by overlaying different illumination channels.

The illumination of the entrance pupil of the projection optical unit 10 may be defined geometrically by an arrangement of the second facets 23. The intensity distribution in the entrance pupil of the projection optical unit 10 may be set by selecting the illumination channels, for example the subset of the second facets 23, which guide light. This intensity distribution is also referred to as illumination setting or illumination pupil filling.

A likewise preferred pupil uniformity in the region of portions of an illumination pupil of the illumination optical unit 4 which are illuminated in a defined manner may be achieved by a redistribution of the illumination channels.

Further aspects and details of the illumination of the object field 5 and for example of the entrance pupil of the projection optical unit 10 are described hereinafter.

The projection optical unit 10 may for example have a homocentric entrance pupil. The latter may be accessible. It may also be inaccessible.

The entrance pupil of the projection optical unit 10 regularly cannot be exactly illuminated with the second facet mirror 22. When imaging the projection optical unit 10, which images the centre of the second facet mirror 22 telecentrically onto the wafer 13, the aperture rays often do not intersect at a single point. However, it is possible to find an area in which the spacing of the aperture rays that is determined in pairs becomes minimal. This area represents the entrance pupil or an area in real space that is conjugate thereto. For example, this area has a finite curvature.

It may be the case that the projection optical unit 10 has different poses of the entrance pupil for the tangential beam path and for the sagittal beam path. In this case, an imaging element, for example an optical component of the transfer optical unit, should be provided between the second facet mirror 22 and the reticle 7. With the aid of this optical element, the different pose of the tangential entrance pupil and the sagittal entrance pupil can be taken into account.

In the arrangement of the component parts of the illumination optical unit 4 shown in FIG. 1, the second facet mirror 22 is arranged in an area conjugate to the entrance pupil of the projection optical unit 10. The first facet mirror 20 is arranged so as to be tilted in relation to the object plane 6. The first facet mirror 20 is arranged so as to be tilted with respect to an arrangement plane defined by the deflection mirror 19. The first facet mirror 20 is arranged so as to be tilted in relation to an arrangement plane defined by the second facet mirror 22.

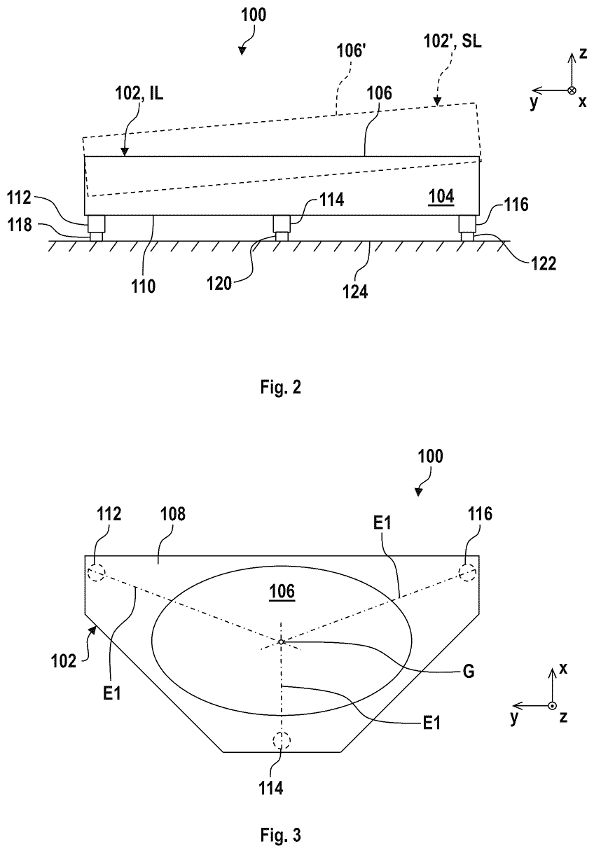

FIG. 2 shows a schematic view of an embodiment of an optical system 100 for the projection exposure apparatus 1. FIG. 3 shows a schematic plan view of the optical system 100. In the following text, reference is made to FIGS. 2 and 3 simultaneously.

The optical system 100 may be a projection optical unit 4 as explained above or part of such a projection optical unit 4. Therefore, the optical system 100 can also be referred to as projection optical unit. However, the optical system 100 may also be an illumination system 2 as previously explained, or part of such an illumination system 2. Therefore, the optical system 100 can alternatively also be referred to as illumination system. However, the following text assumes that the optical system 100 is a projection optical unit 4 or part of such a projection optical unit 4. The optical system 100 is suitable for EUV lithography. However, the optical system 100 can also be suitable for DUV lithography.

The optical system 100 may comprise a plurality of optical elements 102, of which only one is shown in FIGS. 2 and 3 however. Therefore, only one optical element 102 is discussed below. The optical element 102 may be one of the mirrors M1 to M6. For example, the optical element 102 is the mirror M5. The optical element 102 comprises a substrate 104 and an optically effective surface 106, for example a mirror surface. The substrate 104 can also be referred to as mirror substrate. The substrate 104 may comprise glass, ceramic, glass ceramic or other suitable materials.

The optically effective surface 106 is provided on a front side 108 of the substrate 104. The optically effective surface 106 can be realized with the aid of a coating applied to the front side 108. The optically effective surface 106 is a mirror surface. The optically effective surface 106 is suitable for reflecting illumination radiation 16, for example EUV radiation, during operation of the optical system 100. The optically effective surface 106 may have an oval or elliptical geometry in the plan view according to FIG. 3. The optical element 102 or the substrate 104 may have a triangular geometry. In general, however, there can be any desired geometry.

The optical element 102 has a back side 110 facing away from the optically effective surface 106 or the front side 108. The back side 110 has no defined optical properties. That is to say for example that the back side 110 is not a mirror surface and therefore also does not have reflective properties.

A plurality of mirror sockets 112, 114, 116 are provided on the back side 110. However, the mirror sockets 112, 114, 116 can also be positioned on or at the front side 108, especially next to the optically effective surface 106. The mirror sockets 112, 114, 116 can be adhesive sockets. A first mirror socket 112, a second mirror socket 114 and a third mirror socket 116 are provided. In other words, the optical element 102 comprises exactly three mirror sockets 112, 114, 116. The mirror sockets 112, 114, 116 can have geometrically identical designs. The mirror sockets 112, 114, 116 extend in the orientation of FIG. 2 on the underside out of the back side 110. The mirror sockets 112, 114, 116 may be adhesively bonded to the substrate 104. The mirror sockets 112, 114, 116 form corners of an imaginary triangle.

The optical element 102 or the optically effective surface 106 has six degrees of freedom, namely three translational degrees of freedom each along the first spatial direction or x-direction x, the second spatial direction or y-direction y and the third spatial direction or z-direction z, and three rotational degrees of freedom each about the x-direction x, the y-direction y and the z-direction z. That is to say that a position and an orientation of the optical element 102 or of the optically effective surface 106 can be determined or described with the aid of the six degrees of freedom.

The “position” of the optical element 102 or of the optically effective surface 106 is in particular understood to mean the coordinates thereof or the coordinates of a measurement point provided on the optical element 102 with respect to the x-direction x, the y-direction y, and the z-direction z. The “orientation” of the optical element 102 or of the optically effective surface 106 is understood to mean in particular its tilt with respect to the three directions x, y, z. That is to say that the optical element 102 or the optically effective surface 106 can be tilted about the x-direction x, the y-direction y, and/or the z-direction z.

This results in the six degrees of freedom for the position and orientation of the optical element 102 or of the optically effective surface 106. A “pose” of the optical element 102 or of the optically effective surface 106 encompasses both its position and its orientation. The term “pose” is accordingly replaceable by the wording “position and orientation”, and vice versa.

FIG. 2 shows an actual pose IL of the optical element 102 or of the optically effective surface 106 in solid lines and a target pose SL of the optical element 102 or of the optically effective surface 106 in dashed lines and with the reference signs 102′ and 106′. The optical element 102 can be brought from its actual pose IL to the target pose SL and vice versa. For example, the optical element 102 in the target pose SL meets specific optical specifications or desired properties that the optical element 102 in the actual pose IL does not meet.

In order to bring the optical element 102 from the actual pose IL to the target pose SL, it is possible for example to spacer or, during operation, to variably actuate the optical element 102 at the mirror sockets 112, 114, 116. In the present case, “to spacer” should be understood to mean that underlay elements, especially what are known as spacers, for example in the form of washers, are laid under the mirror sockets 112, 114, 116. This allows for adjustment or alignment of the optical element 102.

In the present case, an “adjustment” or “alignment” is understood to mean in particular a change in the pose of the optical element 102. For example, the optical element 102 can be brought from the actual pose IL to the target pose SL. The adjustment or alignment of the optical element 102 can thus be carried out in all six aforementioned degrees of freedom.

The mirror sockets 112, 114, 116 are joined to secure ground or a support structure 124 with the aid of joining points 118, 120, 122. The joining points 118, 120, 122 may comprise a screwed connection. The support structure 124 can be a force frame or any other support structure. Each mirror socket 112, 114, 116 is assigned one joining point 118, 120, 122. In particular, this means that exactly three joining points 118, 120, 122 are provided. Each joining point 118, 120, 122 may be assigned two of the aforementioned degrees of freedom. Thus, all six degrees of freedom of the optical element 102 are defined with the aid of the three joining points 118, 120, 122.

A first joining point 118 is assigned to the first mirror socket 112. A second joining point 120 is assigned to the second mirror socket 114. A third joining point 122 is assigned to the third mirror socket 116. The mirror sockets 112, 114, 116 can have identical designs. Accordingly, the joining points 118, 120, 122 also have identical designs. Therefore, only the first mirror socket 112 and the first joining point 118 are discussed below, which are simply referred to hereinbelow as mirror socket 112 and joining point 118, respectively. All explanations given below in relation to the mirror socket 112 are also applicable to the mirror sockets 114, 116, and vice versa. A corresponding statement also applies to the joining point 118 and the joining points 120, 122.

The optical element 102 is statically determined once all six degrees of freedom are defined. Each further additional definition may lead to an overdetermination. Forces, and hence also deformations, may be introduced into the optical element 102 if the optical element 102 is overdetermined. The intention is to avoid this by way of a suitable design of the mirror sockets 112, 114, 116.

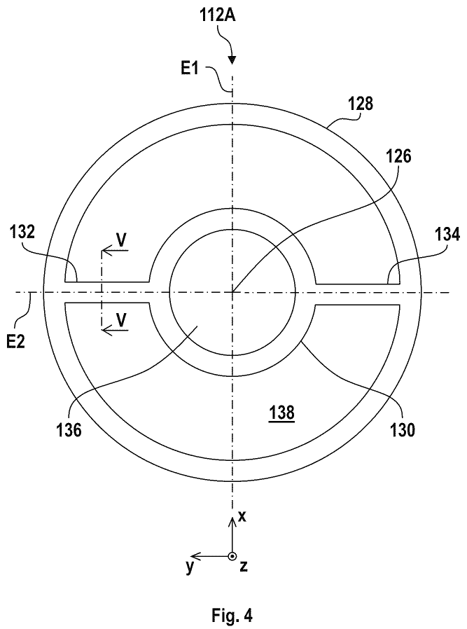

FIG. 4 shows a schematic plan view of an embodiment of a mirror socket 112A as mentioned above. FIG. 5 shows a schematic sectional view of the mirror socket 112A in accordance with the sectional line V-V in FIG. 4. In the following text, reference is made to FIGS. 4 and 5 simultaneously.

The mirror socket 112A is assigned a coordinate system comprising the x-direction x, the y-direction y and the z-direction z. The mirror socket 112A has an axis of symmetry or centre axis 126, in relation to which the mirror socket 112A has a substantially rotationally symmetric structure. However, the mirror socket 112A may also have interfaces or cut surfaces, for example drilled holes or milled sections, which do not have a rotationally symmetric structure. The centre axis 126 corresponds to the z-direction z or is oriented parallel thereto.

The mirror socket 112A comprises an outer part 128 and an inner part 130 placed within the outer part 128. The outer part 128 is ring shaped and may therefore also be referred to as outer ring. The inner part 130 is ring shaped and may therefore also be referred to as inner ring. The outer part 128 is connected to the optical element 102, for example adhesively bonded thereto. The inner part 130 is connected to the joining point 118, for example by screwing and/or clamping. The inner part 130 can be part of the joining point 118. Viewed along the z-direction z, the stiffness of the mirror socket 112A is greater than along the directions x, y.

The x-direction x and the z-direction z or the x-direction x and the centre axis 126 span a first plane E1. The y-direction y and the z-direction z or the y-direction y and the centre axis 126 span a second plane E2. The mirror socket 112A has a mirror symmetrical structure with respect to each of the first plane E1 and the second plane E2. The planes E1, E2 intersect in the centre axis 126. The planes E1, E2 are aligned perpendicular to one another.

As shown in FIG. 3, the three mirror sockets 112, 114, 116 are placed so that the three first planes E1 intersect in a common straight line of intersection or line of intersection G. The line of intersection G runs parallel to the z-direction z or coincides therewith. The line of intersection G intersects the optically effective surface 106.

Now, returning to FIGS. 4 and 5, the outer part 128 is connected to the inner part 130 with the aid of connecting parts 132, 134. A first connecting part 132 and a second connecting part 134 are provided. The outer part 128, the inner part 130 and the connecting parts 132, 134 can be formed in integral, for example materially integral, fashion. Here, “one piece” or “integral” means that, in particular, the outer part 128, the inner part 130 and the connecting parts 132, 134 form a common component, specifically the mirror socket 112A, and are not put together from different subcomponents. In the present case, “materially integral” means that the outer part 128, the inner part 130 and the connecting parts 132, 134 are fabricated from the same material throughout.

The connecting parts 132, 134 extend along the y-direction y. As a result, the mirror socket 112A viewed in the y-direction y has a greater stiffness than viewed in the x-direction x. In the present case, the “stiffness” should be understood to mean the resistance of a body, specifically the mirror socket 112A, to an elastic deformation impressed thereon by the external load and conveys the relationship between the load on the body and its deformation. The stiffness is determined by the material in the body and its geometry. Thus, the stiffness of the mirror socket 112A can be influenced by changing a geometry of the connecting parts 132, 134.

In this case, the force flow is routed from the inner part 130 to the outer part 128 via the connecting parts 132, 134, or vice versa, with the deformation of the connecting parts 132, 134 decisively defining the stiffness. In this case, the force can be introduced at the inner part 130, with the outer part 128 being connected to the optical element 102. Conversely, the force can also be introduced at the outer part 128, with the inner part 130 being connected to the optical element 102 in this case.

The inner part 130 has a circular perforation 136, for example in the form of a circular drilled hole. The inner part 130 can have interfaces, for example in the form of the perforation 136, to the surroundings. The perforation 136 can be annular. However, threaded drilled holes, adhesive joints or the like are also possible as interfaces. A gap 138 is provided between the outer part 128 and the inner part 130. The connecting parts 132, 134 pass through the gap 138, with the result that the connecting parts 132, 134 bridge the gap 138.

As shown in FIG. 5, the connecting parts 132, 134 have a cross-sectional area 140, depicted by hatching, optionally with a rectangular geometry. The cross-sectional area 140 can be rectangular and comprises a connecting part height h running in the z-direction z and a connecting part width b running in the x-direction x. The connecting part height h is greater than the connecting part width b. The stiffness of the connecting parts 132, 134 can be modified by changing a ratio of the connecting part height h to the connecting part width b. In general, the cross-sectional area 140 can have any desired geometry. For example, the cross-sectional area 140 can also be square, trapezoidal, round, triangular, cruciform or the like.

Every connecting part 132, 134 has a top side 142, a bottom side 144 distant from the top side 142 and two side faces 146, 148. The connecting parts 132, 134 are elastically deformable, for example resiliently deformable. That is to say, the connecting parts 132, 134 are reversibly deformable. In this case, “resilient” means that the connecting parts 132, 134 can be brought from a non-deformed state into a deformed state by the application of a force or moment. As soon as this force or this moment no longer acts, the connecting parts 132, 134 are brought back automatically from the deformed state to the non-deformed state.

The mirror socket 112A has its least stiffness viewed in the x-direction x and its greatest stiffness viewed in the z-direction z. The stiffness viewed in the z-direction z is greater than viewed in the x-direction x and greater than viewed in the y-direction y. As a result of the mirror socket 112A being more flexible viewed in the x-direction x than viewed in the y-direction y, it is possible to obtain better mechanical decoupling of the optical element 102 from the support structure 124.

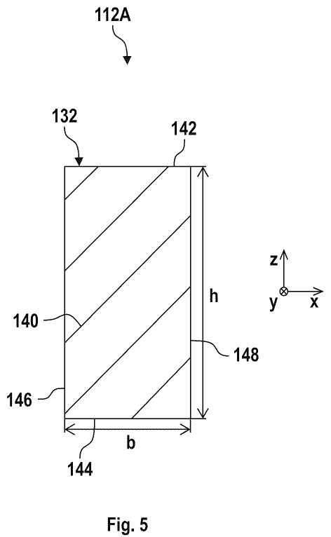

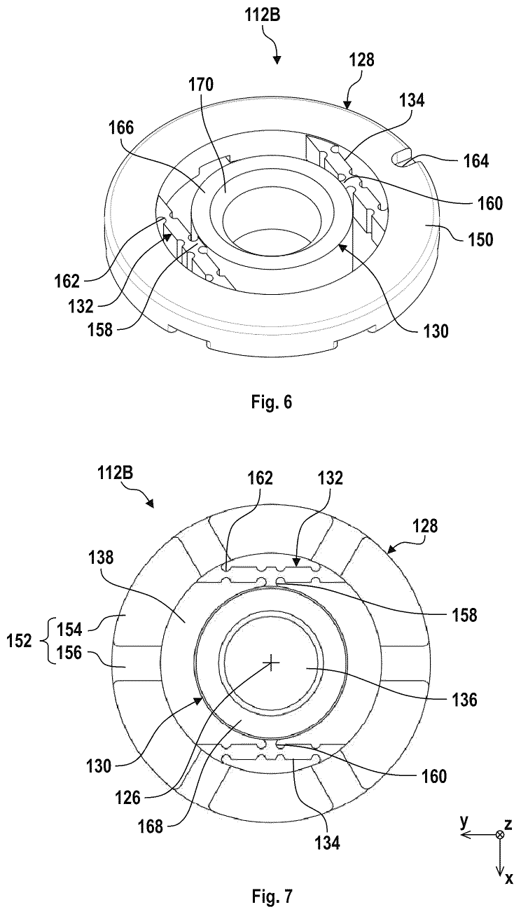

FIG. 6 shows a schematic perspective view of an embodiment of a mirror socket 112B. FIG. 7 shows a schematic back view of the mirror socket 112B. Hereinbelow, FIGS. 6 and 7 are referred to jointly.

In terms of its structure, the mirror socket 112B corresponds to the mirror socket 112A. The mirror socket 112B comprises an outer part 128 and an inner part 130, which are constructed in rotationally symmetric fashion with respect to a centre axis 126. The outer part 128 has a front side 150 facing away from the optical element 102 and a back side 152 facing the optical element 102.

The back side 152 is integrally bonded to the optical element 102, for example adhesively bonded thereto. Integrally bonded connections are connections in which the connection partners are held together by atomic or molecular forces. At the same time, they are non-releasable connections that can be separated only by destruction of the connection mechanism and/or the connection partners.

A plurality of adhesive pads or adhesive regions 154 are provided on the back side 152, but only one of these has been provided with a reference sign in FIG. 7. The adhesive regions 154 are arranged distributed uniformly about the centre axis 126. The adhesive regions 154 alternate with adhesive-free regions 156. That is to say, one region 156 is arranged between two adhesive regions 154, and vice versa. Viewed in the z-direction z, the regions 156 are set back vis-à-vis the adhesive regions 154. An adhesive (not shown), for example an epoxy resin or a cyanoacrylate, is provided on the adhesive regions 154. The inner part 130 is connected to the outer part 128 with the aid of connecting parts 132, 134. The connecting parts 132, 134 extend along the y-direction y. Viewed in the x-direction x, the inner part 130 is placed between the two connecting parts 132, 134. The inner part 130 is connected to the connecting parts 132, 134 with the aid of ridge-shaped joining points 158, 160.

Each connecting part 132, 134 has a plurality of flexures 162, only one of which has been provided with a reference sign in FIGS. 6 and 7. In the present case, a “flexure” is generally understood to mean a region, for example a cross-sectional narrowing or thinning, of a component, which region enables a relative movement between two rigid-body regions of the component by bending or torsion. For example, the flexures 162 are formed as indentations which are rounded off on both sides and attached to the connecting parts 132, 134. The joining points 158, 160 are placed between two flexures 162. The connecting parts 132, 134 themselves also act as flexures between the outer part 128 and the inner part 130.

To align the mirror socket 112B, the latter has a groove 164 provided on the outer part 128. The inner part 130 has a front side 166 oriented parallel to the front side 150 and a back side 168 oriented parallel to the back side 152. A chamfer 170 facing the perforation 136 is provided on the front side 166.

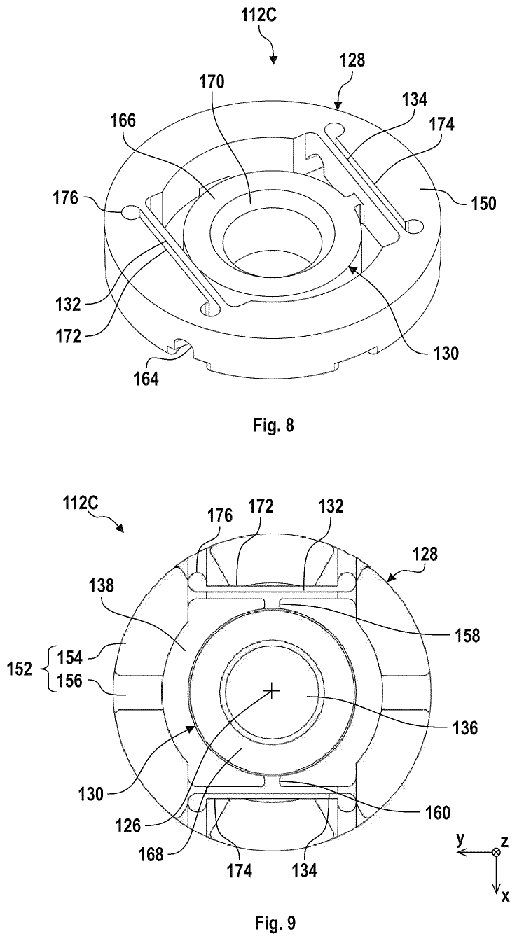

FIG. 8 shows a schematic perspective view of an embodiment of a mirror socket 112C. FIG. 9 shows a schematic back view of the mirror socket 112C. Hereinbelow, FIGS. 8 and 9 are referred to jointly.

In terms of its structure, the mirror socket 112C corresponds to the mirror socket 112A. The mirror socket 112C comprises an outer part 128 and an inner part 130, which are constructed in rotationally symmetric fashion with respect to a centre axis 126. The outer part 128 has a front side 150 facing away from the optical element 102 and a back side 152 facing the optical element 102.

The back side 152 is integrally bonded to the optical element 102, for example adhesively bonded thereto. A plurality of adhesive pads or adhesive regions 154 are provided on the back side 152, but only one of these has been provided with a reference sign in FIG. 9. The adhesive regions 154 are arranged distributed uniformly about the centre axis 126. The adhesive regions 154 alternate with adhesive-free regions 156. That is to say, one region 156 is arranged between two adhesive regions 154, and vice versa. Viewed in the z-direction z, the regions 156 are set back vis-à-vis the adhesive regions 154.

The inner part 130 is connected to the outer part 128 with the aid of connecting parts 132, 134. The connecting parts 132, 134 extend along the y-direction y. Viewed in the x-direction x, the inner part 130 is placed between the two connecting parts 132, 134. The inner part 130 is connected to the connecting parts 132, 134 with the aid of ridge-shaped joining points 158, 160.

The connecting parts 132, 134 have been cut free from the outer part 128 with the aid of slots 172, 174. Drilled holes 176 are provided at the ends of the slots 172, 174, only one of which has been provided with a reference sign in FIGS. 8 and 9. Each slot 172, 174 is assigned two drilled holes 176. A cutting wire for wire erosion of the slots 172, 174 can be guided through the drilled holes 176.

The mirror socket 112C has a groove 164 provided on the outer part 128. In this case, the groove 164 serves to reduce the connecting part stiffness. The inner part 130 has a front side 166 oriented parallel to the front side 150 and a back side 168 oriented parallel to the back side 152. A chamfer 170 facing the perforation 136 is provided on the front side 166. Viewed in the z-direction z, the front side 166 has been placed set back vis-à-vis the front side 150.

FIG. 10 shows a schematic perspective view of an embodiment of a mirror socket 112D. FIG. 11 shows a schematic back view of the mirror socket 112D. Hereinbelow, FIGS. 10 and 11 are referred to jointly.

In terms of its structure, the mirror socket 112D corresponds to the mirror socket 112C. The mirror socket 112D differs from the mirror socket 112C only in that the connecting parts 132, 134 do not extend linearly in the y-direction y but instead have an arcuate geometry, for example a circularly arcuate geometry. Accordingly, the slots 172, 174 also have arcuate curvature, for example circularly arcuate curvature.

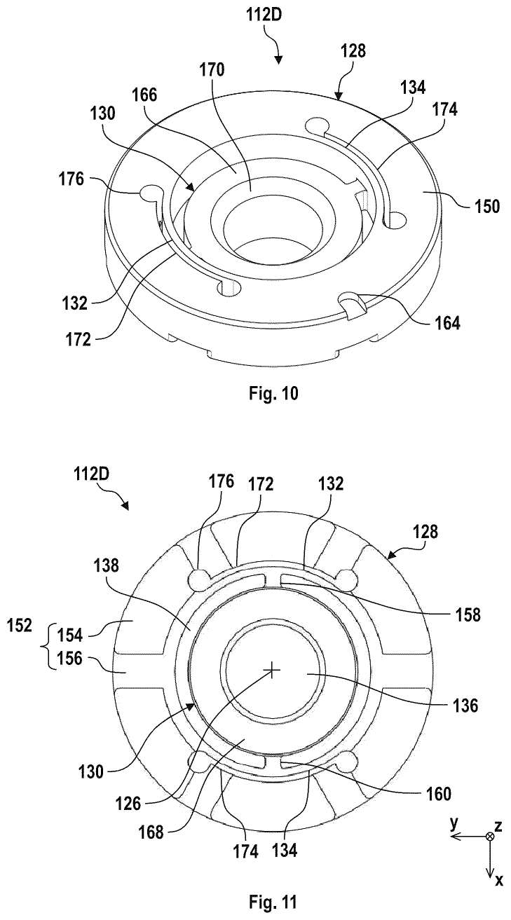

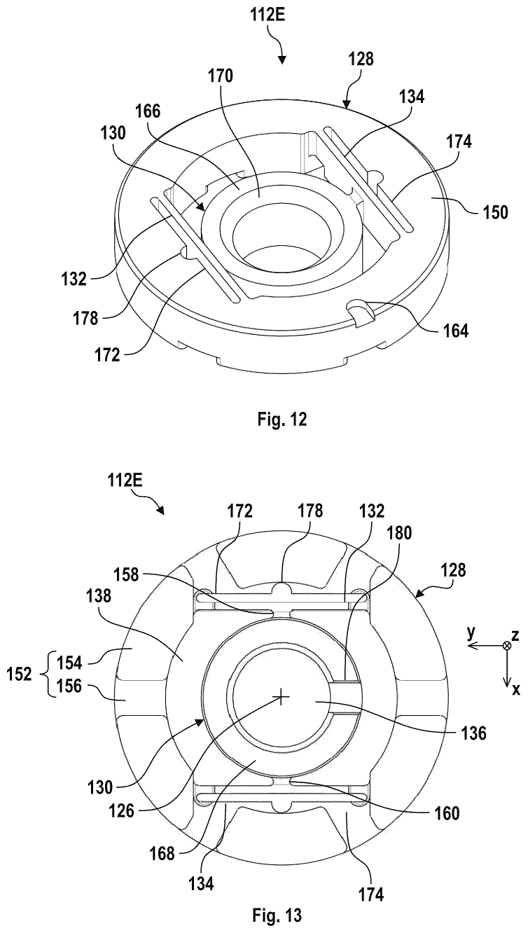

FIG. 12 shows a schematic perspective view of an embodiment of a mirror socket 112E. FIG. 13 shows a schematic back view of the mirror socket 112E. Hereinbelow, FIGS. 12 and 13 are referred to jointly.

In terms of its structure, the mirror socket 112E corresponds to the mirror socket 112C. The mirror socket 112E differs from the mirror socket 112C only in that the slots 172, 174 do not have two drilled holes 176 at their ends but each have a central drilled hole 178. Further, a groove 180 is provided on the inner part 130.

The inner part 130 is fastened centrally to the connecting parts 132, 134, which merge into the outer part 128 at the connecting part ends. On a connecting line of the joining points 158, 160 perpendicular to the connecting parts 132, 134, the inner part 130 is flexibly joined to the connecting parts 132, 134 by way of the connecting points 158, 160. The suitable choice of a rotational orientation of the mirror socket 112E on the optical element 102 depends on the decoupling effect to be obtained and the dynamic performance.

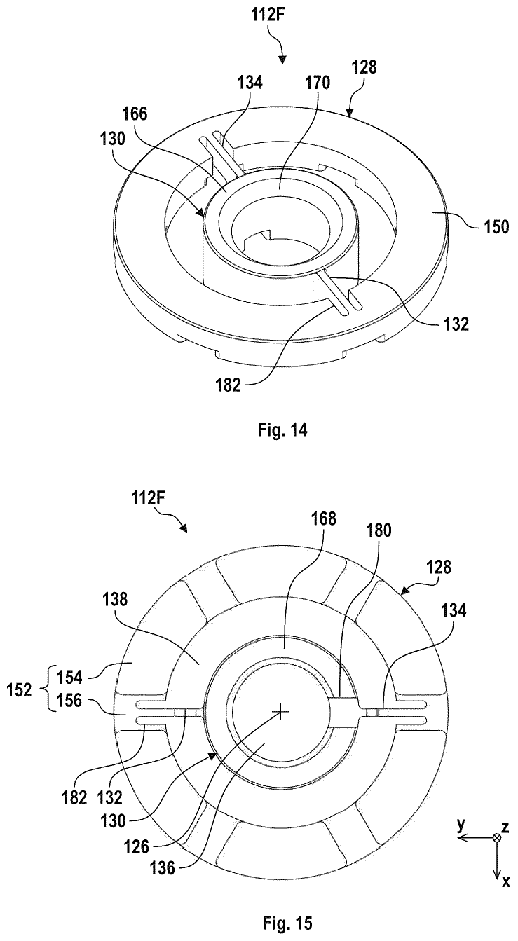

FIG. 14 shows a schematic perspective view of an embodiment of a mirror socket 112F. FIG. 15 shows a schematic back view of the mirror socket 112F. Hereinbelow, FIGS. 14 and 15 are referred to jointly.

In terms of its structure, the mirror socket 112F corresponds to the mirror socket 112A. The mirror socket 112F comprises an outer part 128 and an inner part 130, which are constructed in rotationally symmetric fashion with respect to a centre axis 126. The outer part 128 has a front side 150 facing away from the optical element 102 and a back side 152 facing the optical element 102. The back side 152 is integrally bonded to the optical element 102, for example adhesively bonded thereto.

A plurality of adhesive pads or adhesive regions 154 are provided on the back side 152, but only one of these has been provided with a reference sign in FIG. 15. The adhesive regions 154 are arranged distributed uniformly about the centre axis 126. The adhesive regions 154 alternate with adhesive-free regions 156. That is to say, one region 156 is arranged between two adhesive regions 154, and vice versa. Viewed in the z-direction z, the regions 156 are set back vis-à-vis the adhesive regions 154.

The inner part 130 is connected to the outer part 128 with the aid of connecting parts 132, 134. The connecting parts 132, 134 extend in the y-direction y. Slots 182 are in each case provided on the outer part 128 on both sides of each connecting part 132, 134, but only one of these has been provided with a reference sign in FIGS. 14 and 15. Starting from the gap 138, the slots 182 extend radially into the outer part 128. For example, the slots 182 have been produced with the aid of a wire erosion method.

To align the mirror socket 112F, the latter has a groove 180 provided on the inner part 130. The inner part 130 has a front side 166 oriented parallel to the front side 150 and a back side 168 oriented parallel to the back side 152. A chamfer 170 facing the perforation 136 is provided on the front side 166.

The inner part 130 is suspended on the outer part 128 with the aid of the two straight connecting parts 132, 134 extending in the y-direction y. The mirror socket 112F has a mirror symmetrical structure and joined relatively flexibly in the x-direction x. The desired absolute level of stiffness can be set by way of a respective connecting part length of the connecting parts 132, 134.

For the most flexible joining possible in the x-direction x, the connecting parts 132, 134 have been wire eroded into the edge region of the outer part 128 with the aid of the slots 182. The connecting parts 132, 134 are additionally reinforced in an inner region, for example at the inner part 130, whereby a high axial stiffness along the z-direction z is achieved.

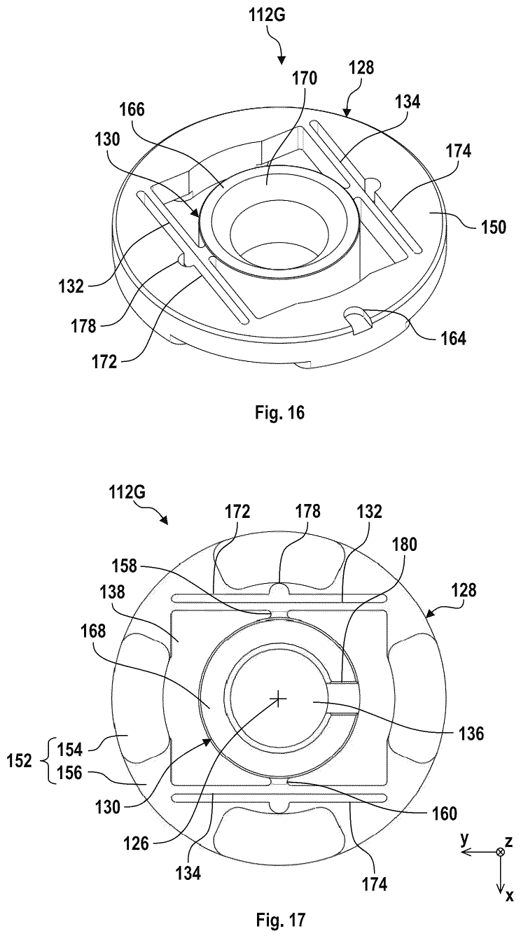

FIG. 16 shows a schematic perspective view of an embodiment of a mirror socket 112G. FIG. 17 shows a schematic back view of the mirror socket 112G. Hereinbelow, FIGS. 16 and 17 are referred to jointly.

In terms of its structure, the mirror socket 112G corresponds to the mirror socket 112E. The mirror socket 112G differs from the mirror socket 112E in that the gap 138 between the inner part 130 and the outer part 128 is not rectangular but cylindrical. This shape of the mirror socket 112G arises because the gap 138 is delimited laterally by the straight connecting parts 132, 134. In contrast to the mirror socket 112E, longer connecting parts 132, 134 which merge into the outer part 128 are provided in the mirror socket 112G. This can achieve an equivalent stiffness behaviour to the mirror socket 112E when using an amagnetic material, for example molybdenum, with a higher Young's modulus.

In the case of the mirror socket 112G, the inner part 130 is suspended on two connecting parts 132, 134, which are fixed on two sides, with the aid of the joining points 158, 160. The arrangement of the connecting parts 132, 134 is mirror symmetric and joined relatively flexibly in the x-direction x. The desired absolute level of stiffness can be set by way of the connecting part length of the connecting parts 132, 134. A high ratio of the stiffness in the z-direction z and the stiffness in the x-direction x is set in a targeted manner by way of the aspect ratio of the cross-sectional area 140 of the connecting parts 132, 134.

Joining the inner part 130 to the connecting parts 132, 134 in the x-direction x leads to little tilt of the joining points 158, 160 in the case of a load in the x-direction x, and hence to a small induced moment about the y-direction y. A cutting wire for fabricating the slots 172, 174 and hence the connecting parts 132, 134 can be introduced through the drilled holes 178 in the central region of the connecting parts 132, 134.

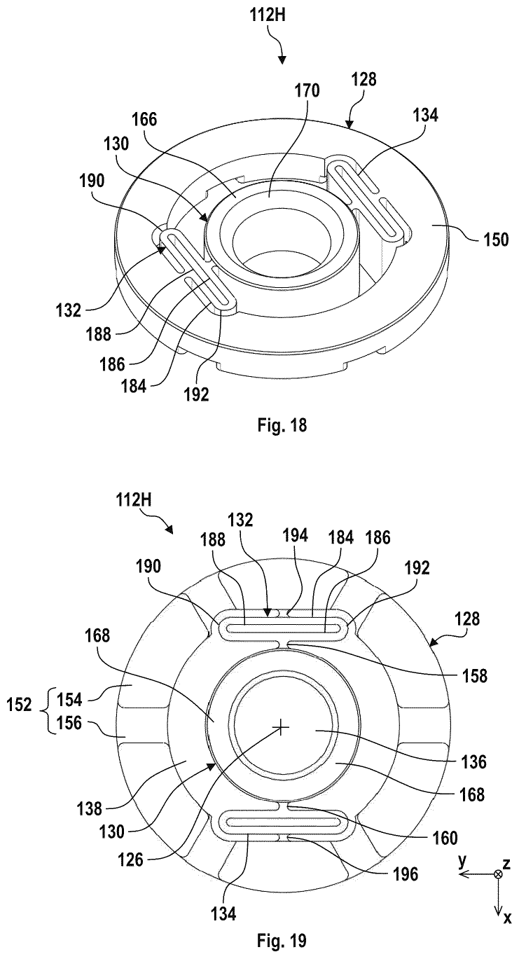

FIG. 18 shows a schematic perspective view of an embodiment of a mirror socket 112H. FIG. 19 shows a schematic back view of the mirror socket 112H. Hereinbelow, FIGS. 18 and 19 are referred to jointly.

In terms of its structure, the mirror socket 112H corresponds to the mirror socket 112E. In contrast to the mirror socket 112E, the mirror socket 112H contains two connecting parts 132, 134, which each comprise two connecting part portions 184, 186 that extend parallel to one another. A slot 188 is provided between the connecting part portions 184, 186. A first connecting part portion 184 and a second connecting part portion 186 are provided. The connecting part portions 184, 186 are connected to one another at deflection portions 190, 192, with the result that the connecting part portions 184, 186 and the deflection portions 190, 192 form a circumferentially closed geometry.

The connecting parts 132, 134 are joined to the inner part 130 with the aid of joining points 158, 160 and to the outer part 128 with the aid of joining points 194, 196. A great connecting part length can be realized and low stiffnesses in the lateral direction can be obtained as a result of the closed ring shape of the connecting parts 132, 134. However, the extent of the straight connecting part shape can be delimited by the outer part 128.

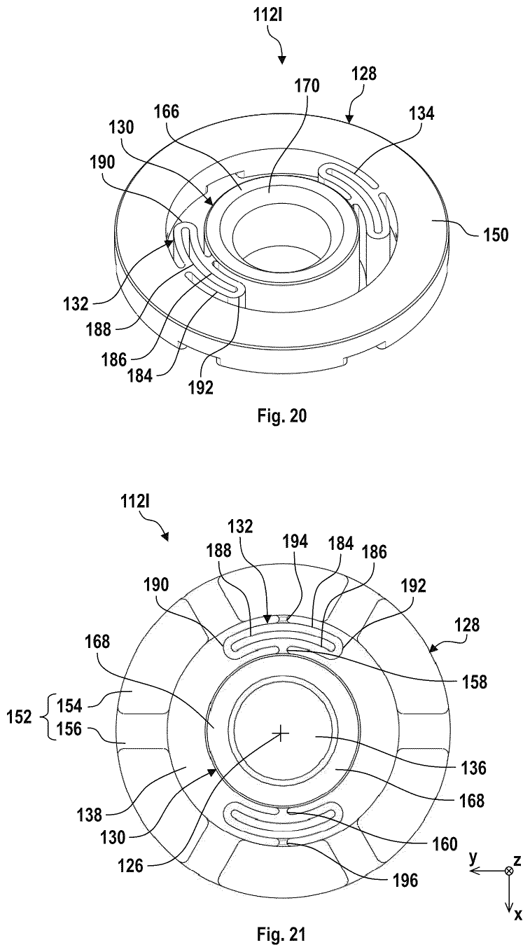

FIG. 20 shows a schematic perspective view of an embodiment of a mirror socket 112I. FIG. 21 shows a schematic back view of the mirror socket 112I. Hereinbelow, FIGS. 20 and 21 are referred to jointly.

In terms of its structure, the mirror socket 112I corresponds to the mirror socket 112H. The mirror socket 112I differs from the mirror socket 112H only in that the connecting parts 132, 134 do not extend linearly in the y-direction y but instead have an arcuate geometry, for example a circularly arcuate geometry. Accordingly, the connecting part portions 184, 186 also have arcuate curvature, for example circularly arcuate curvature.

The advantage of the arcuate connecting parts 132, 134 lies in the longer realizable connecting part length without a collision with the outer part 128. However, the curvature of the connecting parts 132, 134 also has an influence on the stiffness behaviour, with the result that a higher stiffness in the x-direction x than in the case of the mirror socket 112H according to FIGS. 18 and 19 is obtained for the same connecting part length.

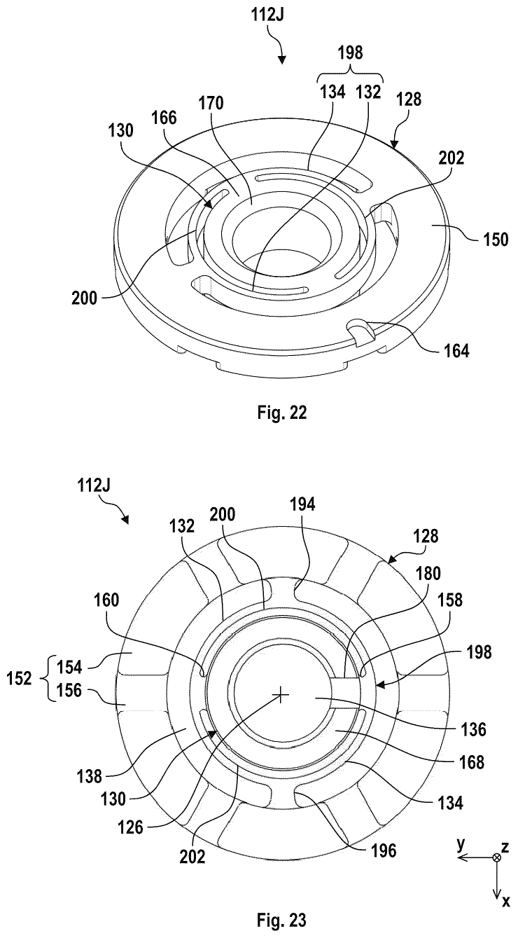

FIG. 22 shows a schematic perspective view of an embodiment of a mirror socket 112J. FIG. 23 shows a schematic back view of the mirror socket 112J. Hereinbelow, FIGS. 22 and 23 are referred to jointly.

In terms of its structure, the mirror socket 112J corresponds to the mirror socket 112E. In contrast to the mirror socket 112E, the mirror socket 112J has two arcuately, for example circularly arcuately, curved connecting parts 132, 134, which jointly form a closed ring connecting part 198, which runs around the inner part 130 in full. The ring connecting part 198 is joined to the inner part 130 via two joining points 158, 160. The ring connecting part 198 is also joined to the outer part 128 via two joining points 194, 196. The joining points 158, 160 and the joining points 194, 196 are placed with an offset of 90° from one another. Slots 200, 202 are provided between the inner part 130 and the ring connecting part 198.

In the orientation of FIG. 23, the ring connecting part 198 is joined to the outer part 128 top and bottom with the aid of the joining points 194, 196. In the orientation of FIG. 23, the inner part 130 is joined to the ring connecting part 198 to the right and left. In comparison with the axial z-direction z, the join is relatively stiff laterally.

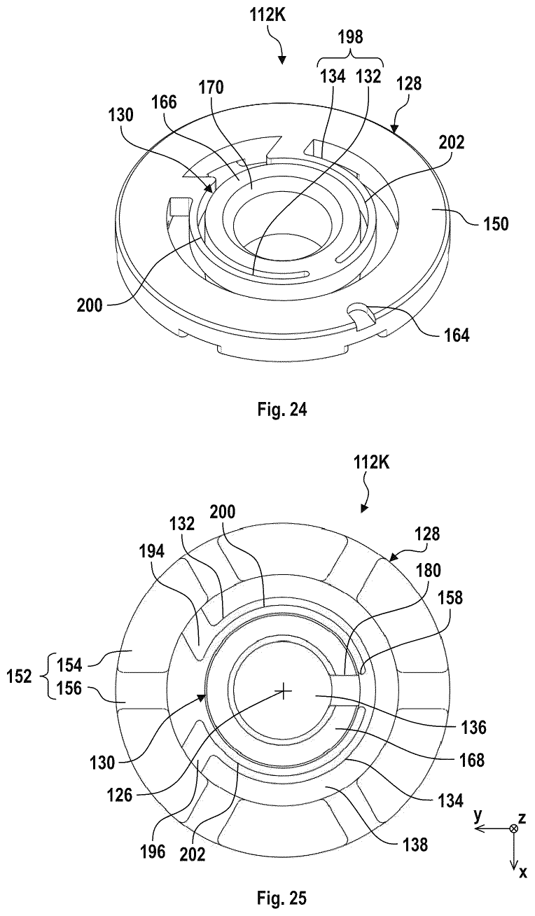

FIG. 24 shows a schematic perspective view of an embodiment of a mirror socket 112K. FIG. 25 shows a schematic back view of the mirror socket 112K. Hereinbelow, FIGS. 24 and 25 are referred to jointly.

In terms of its structure, the mirror socket 112K corresponds to the mirror socket 112J. In contrast to the mirror socket 112J, the ring connecting part 198 formed by the connecting parts 132, 134 of the mirror socket 112K is not closed but open. The ring connecting part 198 is connected to the inner part 130 with the aid of a joining point 158 and connected to the outer part 128 with the aid of two joining points 194, 196. As a result of the ring connecting part 198 not being closed but open, the stiffness of the join is very flexible.

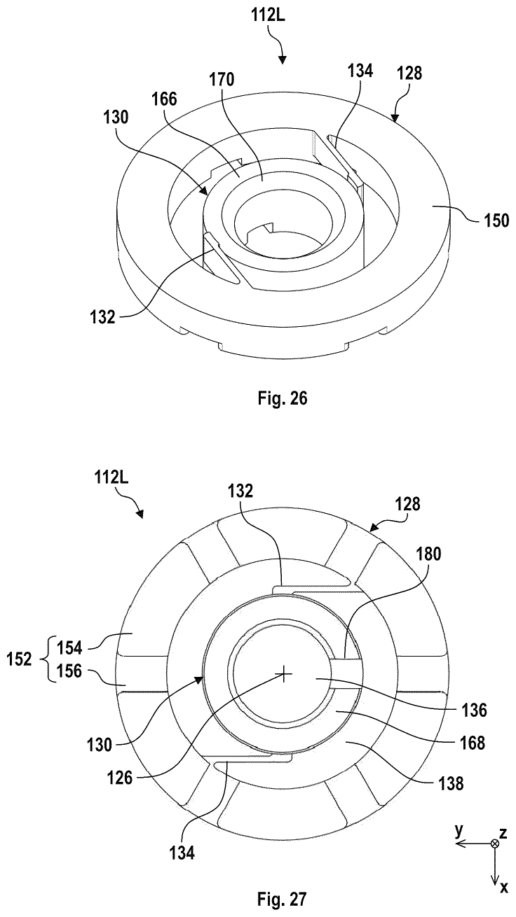

FIG. 26 shows a schematic perspective view of an embodiment of a mirror socket 112L. FIG. 27 shows a schematic back view of the mirror socket 112L. Hereinbelow, FIGS. 26 and 27 are referred to jointly.

In terms of its structure, the mirror socket 112L substantially corresponds to the structure of the mirror socket 112F. In contrast to the mirror socket 112F, the connecting parts 132, 134 are placed spaced apart from one another viewed in the x-direction x in the case of the mirror socket 112L, with the result that there is a non-symmetrical suspension of the inner part 130 on the outer part 128. The inner part 130 is joined to the outer part 128 on one side with the aid of the connecting parts 132, 134.

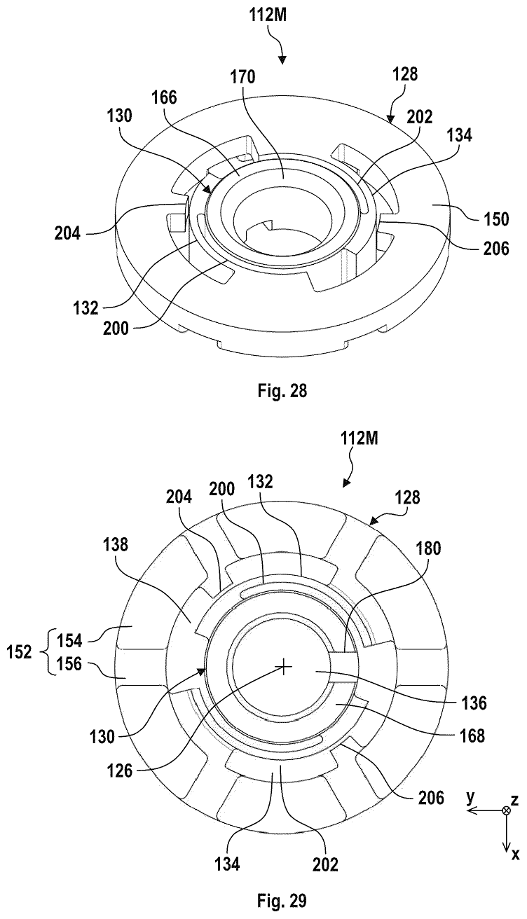

FIG. 28 shows a schematic perspective view of an embodiment of a mirror socket 112M. FIG. 29 shows a schematic back view of the mirror socket 112M. Hereinbelow, FIGS. 28 and 29 are referred to jointly.

In terms of its structure, the mirror socket 112M substantially corresponds to the structure of the mirror socket 112L. In contrast to the mirror socket 112L, the connecting parts 132, 134 of the mirror socket 112M are not straight but extend arcuately, for example circularly arcuately, about the inner part 130. Stops 204, 206 for the inner part 130 which extend into the gap 138 in the direction of the inner part 130 are provided on the outer part 128.

The mirror socket 112M thus has a point symmetric connecting part design with connecting parts 132, 134 fixed on one side. The connecting parts 132, 134 are guided circularly around the inner part 130 and implemented with a long connecting part length in the restricted installation space between the inner part 130 and the outer part 128. The basic stiffness can be adjusted within a large range by varying the connecting part length.

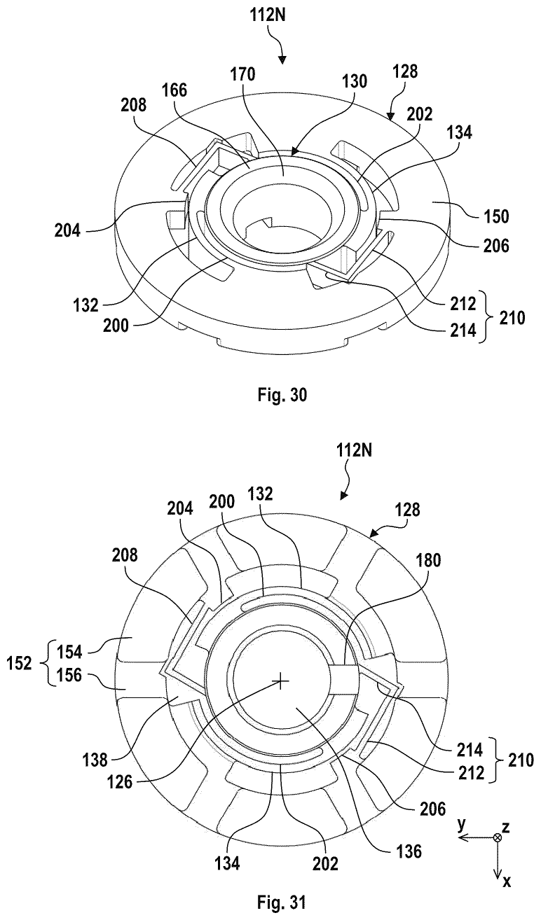

FIG. 30 shows a schematic perspective view of an embodiment of a mirror socket 112N. FIG. 31 shows a schematic back view of the mirror socket 112N. Hereinbelow, FIGS. 30 and 31 are referred to jointly.

In terms of its structure, the mirror socket 112N substantially corresponds to the structure of the mirror socket 112M. In contrast to the mirror socket 112M, additional leaf springs 208, 210 are provided in the mirror socket 112M. A first leaf spring 208 and a second leaf spring 210 are provided. The leaf springs 208, 210 extend from the stops 204, 206 and, in addition to the curved connecting parts 132, 134, connect the outer part 128 to the inner part 130.

The leaf springs 208, 210 are folded. Each leaf spring 208, 210 has a first leaf spring portion 212 and a second leaf spring portion 214. The leaf spring portions 212, 214 are placed perpendicular to one another. The folded leaf springs 208, 210 bring about a high axial stiffness in the z-direction z without significantly changing the lateral stiffnesses in the x-direction x and in the y-direction y.

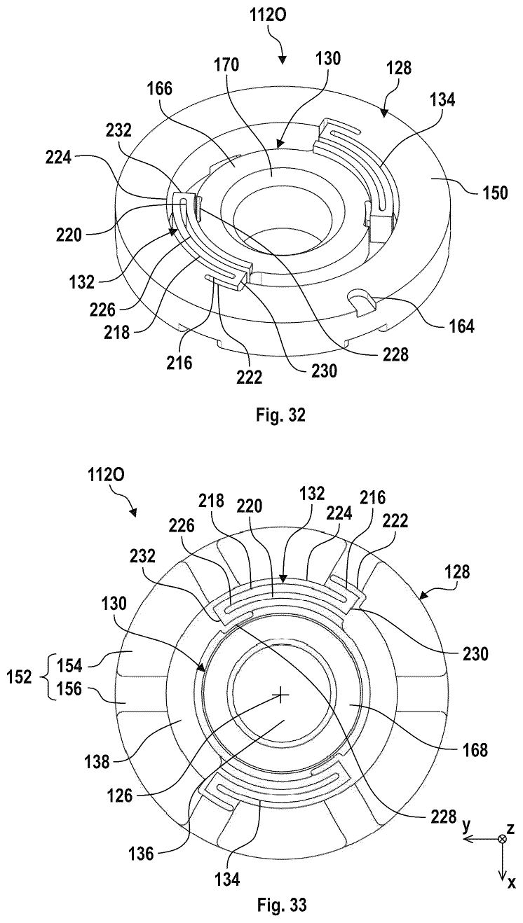

FIG. 32 shows a schematic perspective view of an embodiment of a mirror socket 112O. FIG. 33 shows a schematic back view of the mirror socket 112O. Hereinbelow, FIGS. 32 and 33 are referred to jointly.

In terms of its structure, the mirror socket 112O corresponds to the mirror socket 112E. In contrast to the mirror socket 112E, the mirror socket 112O contains two connecting parts 132, 134, which each comprise a plurality of arcuately, for example circularly arcuately, curved connecting part portions 216, 218, 220. With the aid of slots 222, 224, 226, 228, the connecting part portions 216, 218, 220 are cut free from one another, from the outer part 128 and from the inner part 130. The connecting part portions 216, 218, 220 are connected to one another with the aid of deflection portions 230, 232.

The profile of the connecting parts 132, 134 from the inner part 130 to the outer part 128 is folded multiple times, whereby a very long connecting part length can be obtained. The inner part 130 can be joined very flexibly to the outer part 128. The connecting parts 132, 134 have a zigzag-shaped or meandering geometry on account of the folded geometry. All embodiments of the mirror socket 112A, 112B, 112C, 112D, 112E, 112F, 112G, 112H, 112I, 112J, 112K, 112L, 112M, 112N, 112O can be fabricated from an amagnetic or nonmagnetic material or substance. As a result, parasitic forces and moments caused by relatively strong magnetic fields can be minimized. By way of example, use can be made of molybdenum. In the case where no amagnetic material is used, use can be made of an iron-nickel alloy, for example Invar, for example.

The mirror socket 112A, 112B, 112C, 112D, 112E, 112F, 112G, 112H, 112I, 112J, 112K, 112L, 112M, 112N, 112O enables directionally dependent decoupling of forces and moments. The mirror socket 112A, 112B, 112C, 112D, 112E, 112F, 112G, 112H, 112I, 112J, 112K, 112L, 112M, 112N, 112O is adapted to the mechanical properties, for example the high Young's modulus of molybdenum, of the chosen amagnetic materials. This allows for a reduction of deformations of the optically effective surface 106 (surface figure deformation, SFD) on the mirror socket 112A, 112B, 112C, 112D, 112E, 112F, 112G, 112H, 112I, 112J, 112K, 112L, 112M, 112N, 112O by external influences and of magnetic effects of the mirror socket 112A, 112B, 112C, 112D, 112E, 112F, 112G, 112H, 112I, 112J, 112K, 112L, 112M, 112N, 112O itself, and hence an improvement in the imaging quality.

The redesign of the mirror socket 112A, 112B, 112C, 112D, 112E, 112F, 112G, 112H, 112I, 112J, 112K, 112L, 112M, 112N, 112O from an amagnetic material serves to reduce parasitic forces, for example as a result of magnetostriction effects when using the mirror socket 112A, 112B, 112C, 112D, 112E, 112F, 112G, 112H, 112I, 112J, 112K, 112L, 112M, 112N, 112O in relatively strong magnetic fields. The previously used Invar material is replaced by molybdenum. As a relevant mechanical parameter, the Young's modulus of the new molybdenum material is approximately 2.3-times higher at E_{Mo}=320 GPa (E_{Invar}=1.37 GPa).

By adapting the geometry of the mirror socket 112A, 112B, 112C, 112D, 112E, 112F, 112G, 112H, 112I, 112J, 112K, 112L, 112M, 112N, 112O, for example of the connecting parts 132, 134, the intention is to achieve an equivalent stiffness behaviour of the mirror socket 112A, 112B, 112C, 112D, 112E, 112F, 112G, 112H, 112I, 112J, 112K, 112L, 112M, 112N, 112O, with the result that the behaviour with respect to SFD and dynamics is maintained unchanged.

The mirror socket 112A, 112B, 112C, 112D, 112E, 112F, 112G, 112H, 112I, 112J, 112K, 112L, 112M, 112N, 112O is implemented by a two-part structure. The outer part 128 and the inner part 130 are connected to one another by the connecting parts 132, 134. In this case, viewed in the x-direction x, the inner part 130 can be flexibly joined to the outer part 128, with the result that a decoupling effect is achieved and deformations of the optical element 102 can be kept as low as possible. The join in the axial z-direction z is as stiff as possible for good dynamic behaviour of the optical element 102 with a high bandwidth. The join stiffnesses of the connecting parts 132, 134 can be set in a targeted manner by way of the shape and dimensions of the connecting parts 132, 134.

There are fabrication-related and installation space-related boundary conditions for the design of the mirror socket 112A, 112B, 112C, 112D, 112E, 112F, 112G, 112H, 112I, 112J, 112K, 112L, 112M, 112N, 112O which involve corresponding dimensioning of the mirror socket 112A, 112B, 112C, 112D, 112E, 112F, 112G, 112H, 112I, 112J, 112K, 112L, 112M, 112N, 112O. For example, the inner part 130 has an external diameter of approximately 10 mm. The outer part 128 for example has an external diameter of approximately 20 mm.

The desired geometries of the connecting parts 132, 134 can be produced by wire erosion on a component previously machined by turning and milling, from which desired properties arise in respect of the structure dimensions. As a rule, it is possible to fabricate connecting part widths b and gap widths of approximately 0.4 mm and more. However, smaller structures are also possible by way of suitable manufacturing processes. The design of the mirror socket 112A, 112B, 112C, 112D, 112E, 112F, 112G, 112H, 112I, 112J, 112K, 112L, 112M, 112N, 112O allows the inclusion of features that enable a simple production. One example thereof is a drilled through-hole, through which a cutting wire can be inserted into the design.

The magnitude of the stiffness can be set by way of the respective connecting part length of the connecting parts 132, 134 and/or the cross-sectional area 140. An aspect ratio of the connecting part height h to the connecting part width b determines a stiffness ratio c(z)/c(x). The object is a ratio of c(z)/c(x)=10 or more, without the stiffness in the axial direction dropping below c(z)=approximately 107 N/m. Therefore, cross-sectional areas 140 with the greatest possible connecting part height h can be used. The stiffness and stress can be optimized by varying the cross-sectional area 140 over the connecting part length. In this case, the arrangement and shape of the connecting parts 132, 134 influences the stiffness.

The object of the mirror socket 112A, 112B, 112C, 112D, 112E, 112F, 112G, 112H, 112I, 112J, 112K, 112L, 112M, 112N, 112O lies in the directionally dependent decoupling of the optical element 102 from the support structure 124 with a relatively stiff socket material, with the result that the optical element 102 is joined in axially stiff and laterally flexible fashion. This is achieved by a suitable geometry of the connecting parts 132, 134 between the inner part 130 and the outer part 128.

For example, the mirror socket 112A, 112B, 112C, 112D, 112E, 112F, 112G, 112H, 112I, 112J, 112K, 112L, 112M, 112N, 112O is distinguished in that the desired stiffness properties can be achieved by adapting the geometry of the connecting parts 132, 134, also by using a different material with a higher Young's modulus, molybdenum in the present case. By changing material to an amagnetic material, the influence of magnetic forces and magnetostriction is minimized. A design of equivalent or better stiffness is obtained by an adapted geometry of the connecting parts 132, 134.

Each embodiment of the mirror socket 112A, 112B, 112C, 112D, 112E, 112F, 112G, 112H, 112I, 112J, 112K, 112L, 112M, 112N, 112O has connecting parts 132, 134 between the inner part 130 and the outer part 128, and these have a sufficient aspect ratio of connecting part height h to connecting part width b for realizing the desired stiffness ratio (lateral/axial) and the connecting part length for setting the absolute stiffness range. This can be effected by wire erosion, for example. The use of an amagnetic material is used in order to reduce the magnetic effects.

Advantageously, the mirror socket 112A, 112B, 112C, 112D, 112E, 112F, 112G, 112H, 112I, 112J, 112K, 112L, 112M, 112N, 112O has drilled holes 176, 178 or perforations of any type or the like for the supply of a wire for wire erosion. In this case, minimum gap widths or connecting part widths b for wire erosion are taken into account.

The stiffness adaptation can be improved again by varying the cross-sectional area 140 of the connecting parts 132, 134 over the connecting part length. It is possible to circumvent installation space restrictions and/or bring about the adjustment of the stiffness by way of a connecting part geometry that is graduated in height. This yields a high ratio of lateral stiffnesses c(y)/c(x).

Any desired manufacturing processes, for example turning, milling, grinding, wire corrosion or the like, can be used to produce the mirror socket 112A, 112B, 112C, 112D, 112E, 112F, 112G, 112H, 112I, 112J, 112K, 112L, 112M, 112N, 112O. The ratio of the lateral stiffnesses c(y)/c(x) is not fixedly prescribed but can be greater than 1 in order to obtain both the desired decoupling of SFD effects and a sufficient dynamic behaviour at the optical element 102.

Amagnetic materials with different mechanical and thermal properties can be used in the mirror socket 112A, 112B, 112C, 112D, 112E, 112F, 112G, 112H, 112I, 112J, 112K, 112L, 112M, 112N, 112O. Nevertheless, there is no loss of system performance due to SFD, thermal and/or dynamic effects as a result of the optimized adaptation of the mirror socket 112A, 112B, 112C, 112D, 112E, 112F, 112G, 112H, 112I, 112J, 112K, 112L, 112M, 112N, 112O.

Although the present disclosure has been described on the basis of exemplary embodiments, it can be modified in diverse ways.

LIST OF REFERENCE SIGNS

| | |
|---|---|
| 1 | Projection exposure apparatus |
| 2 | Illumination system |
| 3 | Light source |
| 4 | Illumination optical unit |
| 5 | Object field |
| 6 | Object plane |
| 7 | Reticle |
| 8 | Reticle holder |
| 9 | Reticle displacement drive |
| 10 | Projection optical unit |
| 11 | Image field |
| 12 | Image plane |
| 13 | Wafer |
| 14 | Wafer holder |
| 15 | Wafer displacement drive |
| 16 | Illumination radiation |
| 17 | Collector |
| 18 | Intermediate focal plane |
| 19 | Deflection mirror |
| 20 | First facet mirror |
| 21 | First facet |
| 22 | Second facet mirror |
| 23 | Second facet |
| 100 | Optical system |
| 102 | Optical element |
| 102′ | Optical element |
| 104 | Substrate |
| 106 | Optically effective |
| 106′ | Optically effective |
| 108 | Front side |
| 110 | Back side |
| 112 | Mirror socket |
| 112A | Mirror socket |
| 112B | Mirror socket |
| 112C | Mirror socket |
| 112D | Mirror socket |
| 112E | Mirror socket |
| 112F | Mirror socket |
| 112G | Mirror socket |
| 112H | Mirror socket |
| 112I | Mirror socket |
| 112J | Mirror socket |
| 112K | Mirror socket |
| 112L | Mirror socket |
| 112M | Mirror socket |
| 112N | Mirror socket |
| 112O | Mirror socket |
| 114 | Mirror socket |
| 116 | Mirror socket |
| 118 | Joining point |
| 120 | Joining point |
| 122 | Joining point |
| 124 | Support structure |
| 126 | Centre axis |
| 128 | Outer part |
| 130 | Inner part |
| 132 | Connecting part |
| 134 | Connecting part |
| 136 | Opening |
| 138 | Gap |
| 140 | Cross-sectional area |
| 142 | Top side |
| 144 | Bottom side |
| 146 | Side face |
| 148 | Side face |
| 150 | Front side |
| 152 | Back side |
| 154 | Adhesive region |
| 156 | Region |
| 158 | Joining point |
| 160 | Joining point |
| 162 | Flexure |
| 164 | Groove |
| 166 | Front side |
| 168 | Back side |
| 170 | Chamfer |
| 172 | Slot |
| 174 | Slot |
| 176 | Drilled hole |
| 178 | Drilled hole |
| 180 | Groove |
| 182 | Slot |
| 184 | Connecting part portion |
| 186 | Connecting part portion |
| 188 | Slot |
| 190 | Deflection portion |
| 192 | Deflection portion |
| 194 | Joining point |
| 196 | Joining point |
| 198 | Ring connecting part |
| 200 | Slot |
| 202 | Slot |
| 204 | Stop |
| 206 | Stop |
| 208 | Leaf spring |
| 210 | Leaf spring |
| 212 | Leaf spring portion |
| 214 | Leaf spring portion |
| 216 | Connecting part portion |
| 218 | Connecting part portion |
| 220 | Connecting part portion |
| 222 | Slot |
| 224 | Slot |
| 226 | Slot |
| 228 | Slot |
| 230 | Deflection portion |
| 232 | Deflection portion |
| b | Connecting part width |
| E1 | Plane |
| E2 | Plane |
| G | Line of intersection |
| h | Connecting part height |
| IL | Actual pose |
| M1 | Mirror |
| M2 | Mirror |
| M3 | Mirror |
| M4 | Mirror |
| M5 | Mirror |
| M6 | Mirror |
| SL | Target pose |
| x | x-direction |
| y | y-direction |
| z | z-direction |

What is claimed is:

1. A mirror socket, comprising:
an outer part;
an inner part within the outer part; and
elastically deformable connecting parts connecting the inner and outer parts
wherein:
mirror socket is integral;
the mirror socket has a centre axis, a first spatial direction perpendicular to the centre axis, and a second spatial direction perpendicular to both the centre axis and the first spatial direction;
the mirror socket has a first stiffness along the first spatial direction and a second stiffness along the second spatial direction; and
the first stiffness is greater than the second stiffness.

2. The mirror socket of claim 1, wherein the elastically deformable connecting parts extend in the first spatial direction.

3. The mirror socket of claim 1, wherein the elastically deformable connecting parts comprise first and second elastically deformable connecting parts, and the inner part is between the first elastically deformable connecting part and the second elastically deformable connecting part.

4. The mirror socket of claim 1, wherein the outer part, the inner part and the elastically deformable connecting parts are integral.

5. The mirror socket of claim 1, the outer part, the inner part and the elastically deformable connecting parts are materially integral.

6. The mirror socket of claim 1, wherein the elastically deformable connecting parts extend parallel to and spaced apart from one another.

7. The mirror socket of claim 6, wherein the elastically deformable connecting parts have arcuate, in particular circularly arcuate, curvature.

8. The mirror socket of claim 1, wherein the elastically deformable connecting parts have arcuate, in particular circularly arcuate, curvature.

9. The mirror socket of claim 1, wherein the elastically deformable connecting parts have circularly arcuate curvature.

10. The mirror socket of claim 1, wherein for each of at least some of elastically deformable connecting parts:
the elastically deformable connecting part comprises a first connecting part portion, a second connecting part portion, and deflection portions; and
the deflection portions connect the first and second connecting part portions so that the elastically deformable connecting part has a circumferentially closed geometry.

11. The mirror socket of claim 1, wherein the elastically deformable connecting parts jointly define a ring connecting part around at least portions of the inner part.

12. The mirror socket of claim 1, wherein:
the elastically deformable connecting parts have a connecting part height along the centre axis; and
starting from the outer part, the connecting part height varies in the direction of the inner part.

13. The mirror socket of claim 1, wherein the mirror socket comprises holes configured to have a cutting wire guided therethrough.

14. The mirror socket of claim 1, wherein the mirror comprises an amagnetic material.

15. An optical system, comprising:
an optical element;
a support structure carrying the optical element; and
a mirror socket according to claim 1,
wherein the mirror socket connects the optical element to the support structure.

16. An optical system, comprising:
an optical element;
a support structure carrying the optical element; and
three mirror sockets according to claim 1,
wherein the three mirror sockets connect the optical element to the support structure, the optical element has six degrees of freedom, and each of the three mirror sockets is assigned exactly two of the degrees of freedom.

17. The optical system of claim 16, wherein each of the three mirror sockets has a plane spanned by the centre axis and a spatial direction viewed along which the mirror socket has the smaller stiffness, and wherein the three mirror sockets are configured so that the planes intersect one another in a common line of intersection.

18. An apparatus, comprising:
a mirror socket according to claim 1,
wherein the apparatus is a projection exposure apparatus.

19. An apparatus, comprising:
an optical system, comprising:
an optical element;
a support structure carrying the optical element; and
a mirror socket according to claim 1,
wherein the mirror socket connects the optical element to the support structure, and the apparatus is a projection exposure apparatus.

20. An apparatus, comprising:
an optical system, comprising:
an optical element;
a support structure carrying the optical element; and
three mirror sockets according to claim 1,
wherein the three mirror sockets connect the optical element to the support structure, the optical element has six degrees of freedom, each of the three mirror sockets is assigned exactly two of the degrees of freedom, and the apparatus is a projection exposure apparatus.
